(19) United States
(12) Patent Application Publication
(10) Pub. No.: US 2026/0331431 A1
(43) Pub. Date: Oct. 22, 2026

(54) PLASMA PROCESSING APPARATUS, PLASMA SOURCE AND PLASMA CONTROL METHOD

(71) Applicant: Tokyo Electron Limited, Tokyo (JP)

(72) Inventors: Kazushi KANEKO, Yamanashi (JP); Satoru KAWAKAMI, Yamanashi (JP)

(21) Appl. No.: 19/695,437

(22) Filed: Jun. 2, 2026

Related U.S. Application Data
(63) Continuation of application No. PCT/JP2024/042081, filed on Nov. 28, 2024.

(30) Foreign Application Priority Data
Dec. 12, 2023 (JP) 2023-209074

(51) Int. Cl. H01J 37/32

(52) U.S. Cl. CPC H01J 37/32348; H01J 37/3211; H01J 37/32357; H01J 37/32449

(57) ABSTRACT

A plasma processing apparatus includes a processing chamber, a substrate holder, and a plasma source. The processing chamber provides a processing space for a substrate. The substrate holder holds the substrate. The plasma source is configured to supply plasma into the processing chamber, and includes a gas supply, a pipe, an electromagnetic wave generator, an electromagnetic wave supply, and a resonator array structure. The gas supply supplies a raw material gas. The pipe connects the gas supply to the processing chamber. The electromagnetic wave generator generates electromagnetic waves for plasma excitation to be supplied into the pipe. The electromagnetic wave supply supplies the electromagnetic waves into the pipe through a dielectric window. The resonator array structure includes resonators which are capable of resonating with a magnetic field component of the electromagnetic waves, each smaller in size than a wavelength of the electromagnetic waves, and arranged in a coplanar direction.

### CROSS-REFERENCE TO RELATED APPLICATION

This application is a bypass continuation application of international application No. PCT/JP2024/042081 having an international filing date of Nov. 28, 2024 and designating the United States, the international application being based upon and claiming the benefit of priority from Japanese Patent Application No. 2023-209074, filed on Dec. 12, 2023, the entire contents of which are incorporated herein by reference.

### TECHNICAL FIELD

The present disclosure relates to a plasma processing apparatus, a plasma source and a plasma control method.

### BACKGROUND

Patent Document 1 discloses an array antenna that includes a plurality of antennas and a plurality of anti-coupling elements arranged at intervals between the plurality of antennas, each of the plurality of anti-coupling elements including a first member connected to a ceiling wall that forms a ground plane in a chamber and a second member connected to a tip of the first member or a vicinity thereof. Patent Document 2 discloses a method that includes providing a substrate in a reaction chamber, depositing a silicon carbide film having a first thickness on the substrate, exposing the silicon carbide film having the first thickness to a remote hydrogen plasma treatment that densifies the silicon carbide film having the first thickness, depositing a silicon carbide film having a second thickness on the silicon carbide film having the first thickness, and exposing the silicon carbide film having the second thickness to a remote hydrogen plasma treatment that densifies the silicon carbide film having the second thickness.

### PRIOR ART DOCUMENTS

### Patent Documents

Patent Document 1: Japanese laid-open publication No. 2021-114360
Patent Document 2: Japanese laid-open publication No. 2020-502797

### SUMMARY

A plasma processing apparatus according to an embodiment includes a processing chamber, a substrate holder, and a plasma source. The processing chamber is configured to provide a processing space for a substrate. The substrate holder is configured to hold the substrate within the processing chamber. The plasma source is configured to supply plasma into the processing chamber, and includes a gas supply, a pipe, an electromagnetic wave generator, an electromagnetic wave supply, and a resonator array structure. The gas supply is configured to supply a raw material gas. The pipe is configured to connect the gas supply to the processing chamber. The electromagnetic wave generator is configured to generate electromagnetic waves for plasma excitation to be supplied into the pipe. The electromagnetic wave supply is configured to supply the electromagnetic waves into the pipe through a dielectric window provided in the pipe. The resonator array structure includes a plurality of resonators which are capable of resonating with a magnetic field component of the electromagnetic waves, each smaller in size than the wavelength of the electromagnetic waves, and arranged in a coplanar direction.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a block diagram showing an example of the configuration of a plasma processing apparatus according to a first embodiment.

FIG. 2 is a schematic cross-sectional view showing an example of the configuration of the plasma processing apparatus according to the first embodiment.

FIG. 3 is a view showing an example of the configuration of a nozzle according to the first embodiment.

FIG. 4 is a cross-sectional view showing an example of a pipe in a remote plasma source according to the first embodiment.

FIG. 5 is a view showing an example of the configuration of a resonator array structure according to the first embodiment.

FIG. 6 is a cross-sectional view showing an example of the A-A cross section in FIG. 5.

FIG. 7 is a view showing an example of the plan-view and the B-B cross section of a single resonator according to the first embodiment.

FIG. 8 is a cross-sectional view showing an example of the C-C cross section in FIG. 7.

FIG. 9 is a cross-sectional view showing an example of the D-D cross section in FIG. 7.

FIG. 10 is a view showing an example of the relationship between the S21 value of a resonator and the frequency of an electromagnetic wave.

FIG. 11 is an explanatory view showing an example of the calculation of the resonance frequency of the resonator according to the first embodiment.

FIG. 12 is a schematic cross-sectional view showing an example of the configuration of a plasma processing apparatus according to Modification 1.

FIG. 13 is a schematic cross-sectional view showing an example of the configuration of a plasma processing apparatus according to Modification 2.

FIG. 14 is a schematic cross-sectional view showing an example of the configuration of a plasma processing apparatus according to Modification 3.

FIG. 15 is a schematic cross-sectional view showing an example of the configuration of a plasma processing apparatus according to Modification 4.

FIG. 16 is a schematic cross-sectional view showing an example of the configuration of a plasma processing apparatus according to Modification 5.

FIG. 17 is a diagram showing an example of a cross-section near a resonator array structure according to Modification 5.

FIG. 18 is a plan view showing an example of the configuration of the resonator array structure according to Modification 5 as viewed from the upstream direction of a pipe.

FIG. 19 is a cross-sectional view showing an example of the F-F cross-section in FIG. 18.

FIG. 20 is a diagram showing an example of a plan-view and a G-G cross-section of the single resonator according to Modification 5.

FIG. 21 is a cross-sectional view showing an example of the I-I cross-section in FIG. 20.

FIG. 22 is a cross-sectional view showing an example of the J-J cross-section in FIG. 20.

FIG. 23 is a view showing an example of the relationship between the position of the ring member and the plasma generation region.

FIG. 24 is a view showing an example of the relationship between the position of the ring member and the plasma generation region.

FIG. 25 is a view showing an example of the relationship between the position of the shield and the plasma generation region.

FIG. 26 is a schematic cross-sectional view showing an example of the configuration of a plasma processing apparatus according to Modification 6.

FIG. 27 is a schematic cross-sectional view showing an example of the configuration of a plasma processing apparatus according to a second embodiment.

FIG. 28 is a view showing an example of a cross section near the resonator array structure according to the second embodiment.

FIG. 29 is a plan view showing an example of the configuration of the resonator array structure according to the second embodiment, as viewed from the downstream direction of a pipe.

FIG. 30 is a view showing an example of the configuration of a card-shaped resonator according to the second embodiment.

FIG. 31 is a view showing an example of the configuration of the card-shaped resonator according to the second embodiment.

FIG. 32 is a view showing another example of the configuration of the card-shaped resonator according to the second embodiment.

FIG. 33 is a view showing an example of the cross section of the card-shaped resonator according to the second embodiment.

FIG. 34 is a perspective view showing an example of the resonator array structure according to the second embodiment.

FIG. 35 is a schematic cross-sectional view showing an example of the configuration of a plasma processing apparatus according to Modification 7.

FIG. 36 is a cross-sectional view showing an example of the K-K cross section in FIG. 35.

FIG. 37 is a view showing an example of the configuration of a resonator according to Modification 7.

FIG. 38 is a schematic cross-sectional view showing an example of the configuration of a plasma processing apparatus according to Modification 8.

FIG. 39 is a view showing an example of a cross section near the resonator array structure according to Modification 8.

FIG. 40 is a schematic cross-sectional view showing an example of the configuration of a plasma processing apparatus according to a third embodiment.

FIG. 41 is a perspective view showing an example of a resonator array structure according to the third embodiment.

FIG. 42 is a schematic cross-sectional view showing an example of the configuration of a plasma processing apparatus according to Modification 9.

FIG. 43 is a block diagram showing an example of the configuration of a plasma processing apparatus according to a fourth embodiment.

FIG. 44 is a diagram showing an example of the plasma diffusion region according to the fourth embodiment.

FIG. 45 is a graph showing an example of the electron density distribution in the plasma diffusion region.

FIG. 46 is a graph showing an example of the electron density distribution in the plasma diffusion region.

FIG. 47 is a graph showing an example of the relationship between the gas flow rate and the electron density.

FIG. 48 is a graph showing an example of the relationship between the power of electromagnetic waves and the diameter of a pipe.

FIG. 49 is a graph showing an example of the relationship between the power density ratio of the electromagnetic waves and the diameter of the pipe.

FIG. 50 is a graph showing an example of the relationship between the time during which a gas remains in the space of the resonator array structure and the diameter of the pipe.

FIG. 51 is a graph showing an example of the relationship between the travel time from plasma generation to the processing chamber and the diameter of the pipe.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Preferred embodiments of a plasma processing apparatus, a plasma source and a plasma control method will be described in detail below with reference to the accompanying drawings. However, the disclosed technique is not limited to the following embodiments.

In a plasma processing apparatus using microwaves for plasma excitation, the power of the microwaves supplied into a processing container may be increased in order to increase the electron density of plasma. The higher the power of the microwaves supplied into the processing container, the higher the electron density of the plasma can be.

It is known that when the plasma electron density reaches a certain upper limit by increasing the power of microwaves supplied to the processing container, the dielectric constant of the space within the processing container becomes negative. This upper limit of electron density is appropriately referred to as a “cutoff density.” The refractive index is also known as an indicator of whether microwaves propagate through a space. The refractive index Nis expressed by the following formula (1).

N=\sqrt{ε}\sqrt{μ} (1)

where ε is the dielectric constant and μ is the magnetic permeability.

Since the magnetic permeability is generally positive, when the dielectric constant of the space within the processing container becomes negative, the refractive index of the space within the processing container becomes a pure imaginary number according to the above formula (1). As a result, the microwaves are attenuated and cannot propagate through the space within the processing container. When the plasma electron density reaches the cutoff density, the microwaves cannot propagate through the space within the processing container, and the power of microwaves is not sufficiently absorbed by the plasma. As a result, there is a problem in that the plasma generated within the processing container is prevented from densifying over a wide area. While the microwaves are described as an example, the same problem also occurs in plasma processing apparatuses that use electromagnetic waves in the very high frequency (VHF) to ultra high frequency (UHF) bands.

A stand-alone remote plasma system is known in which plasma generated in a plasma generation chamber, which is a separate space connected to a processing chamber by a pipe, is introduced into the processing chamber in a plasma processing apparatus. While the stand-alone remote plasma system suppresses the influence of heat, electromagnetic waves and ions supplied from the plasma generation chamber (plasma source), the long distance between the plasma source and the processing target substrate may cause the plasma to diffuse, resulting in a decrease in plasma density (radical density). Furthermore, when a processing gas or plasma is introduced from the plasma generation chamber through a pipe or a nozzle into the processing chamber, reflection, loss, and recombination of ions and radicals may occur due to collision thereof, resulting in a decrease in plasma density (radical density). Such low-density radicals result in a low substrate processing rate. Therefore, it is desirable to generate high-density radicals while suppressing the influence of heat, electromagnetic waves, and ions.

### First Embodiment

### [Configuration of Plasma Processing Apparatus]

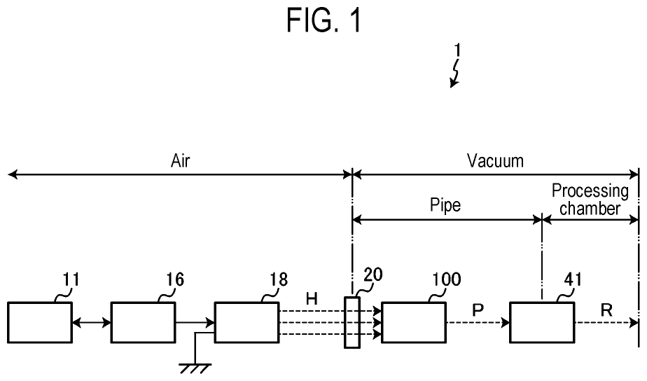

FIG. 1 is a block diagram showing an example of the configuration of a plasma processing apparatus according to a first embodiment. First, the outline of plasma generation using a stand-alone remote plasma system in a plasma processing apparatus 1 will be described with reference to FIG. 1. As shown in FIG. 1, in the plasma processing apparatus 1, a controller 11 controls an RF (radio frequency) power source 16 to generate electromagnetic waves (magnetic field H) using an antenna 18. The electromagnetic waves are then supplied to a plurality of resonators in a resonator array structure 100 installed in a pipe via a dielectric window 20. In the resonator array structure 100, plasma P is generated within the pipe through resonance between the electromagnetic waves and the plurality of resonators. Alternatively, a resonator array structure including an antenna that generates a rotating magnetic field and a plurality of resonators arranged in a direction that resonates with the rotating magnetic field may be used. As the plasma P flows through a pipe toward a nozzle 41, ions are recombined, and radicals R flow from the pipe to the processing chamber through the through-holes of the nozzle 41. The through-holes of the nozzle 41 have a diameter that prevents ions from passing from the pipe to the processing chamber. In the plasma processing apparatus 1, the controller 11 side is kept in an air atmosphere, and the pipe/processing chamber side is kept in a vacuum atmosphere with the dielectric window 20 serving as a boundary. In this embodiment, the part from the RF power source 16 to the resonator array structure 100, or from the RF power source 16 to the nozzle 41, is referred to as a remote plasma source.

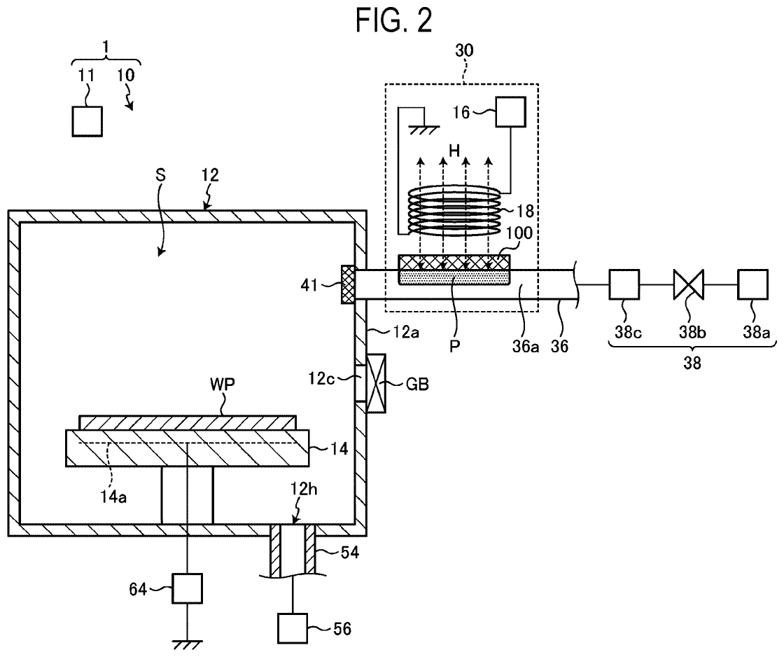

FIG. 2 is a schematic cross-sectional view showing an example of the configuration of the plasma processing apparatus according to the first embodiment. The plasma processing apparatus 1 includes an apparatus body 10 and a controller (an example of a control part) 11. The plasma processing apparatus 1 shown in FIG. 1 is configured, for example, as a plasma processing apparatus in the form of a stand-alone remote plasma system. The apparatus body 10 includes a processing container 12, a stage 14, an RF (Radio Frequency) power source (an example of an electromagnetic wave generator) 16, an antenna 18, a pipe 36, a gas supply 38, and a resonator array structure 100. The apparatus body 10 further includes a nozzle 41. The nozzle 41 is provided on the upper portion of the sidewall 12a of the processing container 12. A remote plasma source 30, which includes at least the RF power source 16, the antenna 18, and the resonator array structure 100, is provided in the pipe 36 connecting the processing container 12 to the gas supply 38. The remote plasma source 30 may also include the gas supply 38.

The processing container 12 is formed in a generally cylindrical shape using, for example, anodized aluminum or the like, and is configured to provide a generally cylindrical processing space S therein. The processing container 12 and the processing space S are an example of a processing chamber. The stage 14 is arranged approximately at the center of the bottom of the processing container 12. An exhaust port 12h for gas exhaust is also provided at the bottom of the processing container 12. An exhaust device 56 including a vacuum pump such as a turbomolecular pump or the like and an automatic pressure control valve is connected to the exhaust port 12h via an exhaust pipe 54. The exhaust device 56 can reduce the pressure in the processing space S to a desired vacuum level. The processing container 12 is grounded for safety. An opening 12c for loading and unloading a workpiece WP is formed in the sidewall 12a of the processing container 12. The opening 12c is opened and closed by a gate valve GB.

The workpiece WP is mounted on the stage 14. The stage 14 is generally disk-shaped and made of ceramics such as AlN or the like. Inside the stage 14, lifting pins (not shown) for raising and lowering the workpiece WP are provided so as to be capable of protruding and retracting relative to the upper surface of the stage 14. The stage 14 has an electrostatic chuck on its upper surface, which holds the workpiece WP. A DC power source 64 is electrically connected to an electrode 14a of the electrostatic chuck. The electrostatic chuck can attract and hold the workpiece WP on its upper surface by an electrostatic force generated by a DC voltage applied from the DC power source 64. The stage 14 is also provided with a temperature control mechanism, such as a coolant flow path and a heater (not shown), for controlling the temperature of the workpiece WP mounted on the stage 14.

The RF power source 16 is coupled to the antenna 18 and configured to generate a source RF signal (source RF power) for plasma generation via at least one impedance matching circuit. In one embodiment, the source RF signal has a frequency within a range of 10 MHz to 3000 MHz. In one embodiment, the RF power source 16 may be configured to generate multiple source RF signals having different frequencies. The one or more source RF signals thus generated are supplied to the antenna 18. As described above, the RF power source 16 is an example of an electromagnetic wave generator and an example of a high-frequency power source. The antenna 18 is also an example of an electromagnetic wave supply.

The antenna 18 includes one or more coils. In one embodiment, the antenna 18 includes a solenoid coil. That is, the antenna 18 is wound in a loop shape. The opening of the antenna 18 may have any shape, such as a circular shape, an elliptical shape, or a polygonal shape (e.g., a square shape or a triangular shape). The RF power source 16 is connected to the antenna 18, and a source RF signal is supplied to the antenna 18. The magnetic field H generated by the antenna 18 is directed to pass through the plurality of resonators of the resonator array structure 100 installed on the sidewall of the pipe 36. The antenna 18 may also be a planar coil formed in a substantially circular spiral shape (planar spiral shape).

The pipe 36 connects the gas supply 38 and the processing space S of the processing container 12. The nozzle 41 is provided at the end of the pipe 36 on the processing space S side. The other end of the pipe 36 is connected to the gas supply 38.

The gas supply 38 may include at least one gas source 38a, at least one valve 38b, and at least one flow rate controller 38c. In one embodiment, the gas supply 38 is configured to supply at least one processing gas from the corresponding gas source 38a to the pipe 36 via the corresponding valve 38b and flow rate controller 38c. Each flow rate controller 38c may include, for example, a mass flow rate controller or a pressure-controlled flow rate controller. Additionally, the gas supply 38 may include one or more flow modulation devices to modulate or pulse the flow rate of the at least one processing gas.

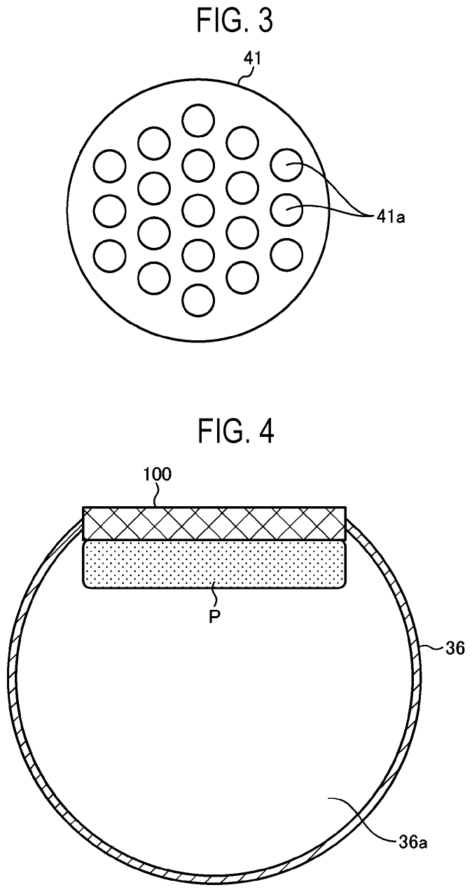

FIG. 3 is a view showing an example of the configuration of the nozzle according to the first embodiment. As shown in FIG. 3, the nozzle 41 has a plurality of through-holes 41a and is arranged to cover the end of the pipe 36 in the cross-sectional direction. Processing gases and radicals are supplied to the processing space S through the plurality of through-holes 41a. The plurality of through-holes 41a preferably have a diameter that prevents ions contained in the plasma generated in the internal space 36a of the pipe 36 from passing into the processing space S. In other words, the ions contained in the plasma are recombined as they pass through the through-holes 41a to form radicals, which are then supplied to the processing space S. The distance between the resonator array structure 100 and the nozzle 41 can be set as desired.

FIG. 4 is a cross-sectional view showing an example of the pipe in the remote plasma source according to the first embodiment. As shown in FIG. 4, the resonator array structure 100 is installed on a portion of the sidewall of the pipe 36. In this case, the resonator array structure 100 also serves as the dielectric window 20. Plasma P is generated in the space in contact with the resonator array structure 100 within the internal space 36a of the pipe 36. In the following description, the cross-sectional direction perpendicular to the longitudinal direction of the pipe 36 is defined as the direction of the cross section in FIG. 4. The resonator array structure 100 may have a curved surface that matches the curved surface of the pipe 36.

Referring again to FIG. 2, the resonator array structure 100 is formed by arranging a plurality of resonators that can resonate with the magnetic field component of electromagnetic waves and have a size smaller than the wavelength of the electromagnetic waves. The resonator array structure is also called a metamaterial, and the resonators are also called metaatoms.

By positioning the resonator array structure 100 on the sidewall of the pipe 36, the electromagnetic waves supplied to the internal space 36a of the pipe 36 by the antenna 18 can resonate with the plurality of resonators of the resonator array structure 100. Resonance between the electromagnetic waves and the plurality of resonators allows the electromagnetic waves to be efficiently supplied to the internal space 36a of the pipe 36, and allows the magnetic permeability of the processing space to become negative. When the magnetic permeability of the internal space 36a is negative, even if the electron density of the plasma generated in the internal space 36a reaches the cutoff density and the dielectric constant of the internal space 36a is negative, the refractive index becomes a real number according to the above formula (1), allowing the electromagnetic waves to propagate in the internal space 36a. Therefore, even if the electron density of the plasma generated in the internal space 36a reaches the cutoff density, the electromagnetic waves can propagate beyond the plasma's skin depth, and the power of the electromagnetic waves is efficiently absorbed by the plasma. As a result, high-density plasma can be generated over a wide area beyond the plasma's skin depth. That is, in the plasma processing apparatus 1 according to this embodiment, the resonator array structure 100 is positioned on the sidewall of the pipe 36, thereby making it possible to realize high density plasma over a wide range within the internal space 36a.

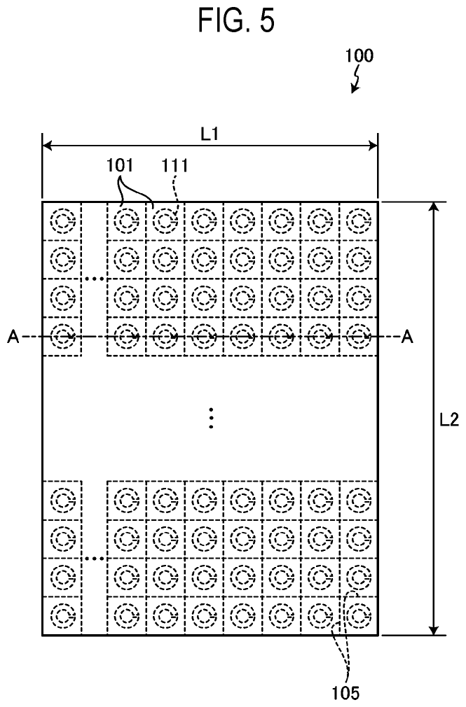

Now, the detailed configuration of the resonator array structure 100 will be described with reference to FIGS. 4 and 5. FIG. 5 is a view showing an example of the configuration of the resonator array structure according to the first embodiment. FIG. 5 shows the resonator array structure 100 as viewed from the antenna 18 side in FIG. 2. The resonator array structure 100 is arranged, for example, so that its longitudinal direction coincides with the longitudinal direction of the pipe 36. In this embodiment, plasma P is generated on the internal space 36a side of the resonator array structure 100.

The resonator array structure 100 is formed by arranging a plurality of resonators 101 in a lattice pattern. Each of the resonators 101 can resonate with the magnetic field component of electromagnetic waves and has a size smaller than the wavelength of the electromagnetic waves. The resonators 101 may also be described as being arranged in a direction of a plane parallel to a first surface 106 (described later) of the resonator array structure 100 on which a base has a larger area, i.e., in a coplanar direction. Specifically, as shown in FIG. 5, the resonators 101 are arranged in the same plane in the flat resonator array structure 100. That is, the resonators 101 are arranged in a plane parallel to the longitudinal surface of the resonator array structure 100. In other words, when viewed from the antenna 18 side, the C-shaped ring members 111, which are shown transparently, are arranged in a lattice pattern so that the C shape is visible. In the resonator array structure 100, the resonators 101 are arranged so as to have a size in column direction (transverse direction) which fits within the diameter of the pipe 36 and a size in row direction (longitudinal direction) which fits within the diameter of the antenna 18. In the example of FIG. 5, the resonator array structure 100 has a length L1 in the column direction and a length L2 in the row direction.

In this case, the boundaries between the plurality of resonators 101 are shown as boundaries 105, but in reality, the plurality of resonators 101 are integrally formed as the resonator array structure 100. The plurality of resonators 101 may be formed separately and fitted into a lattice-shaped frame or glued together to form the resonator array structure 100. Each of the plurality of resonators 101 forms a series resonant circuit consisting of a capacitor equivalent element and a coil equivalent element. The series resonant circuit is realized by patterning a conductor on a plane. The magnetic field H generated by the antenna 18 is directed to pass through the C-shaped ring members 111.

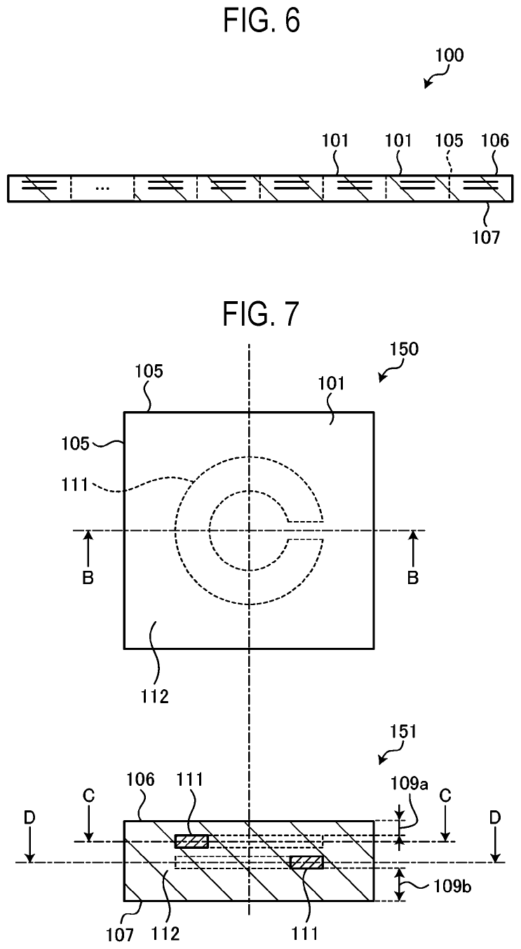

FIG. 6 is a cross-sectional view showing an example of the A-A cross section in FIG. 5. As shown in FIG. 6, in the A-A cross section of the resonator array structure 100, cross sections of the plurality of resonators 101 appear side by side. As in FIG. 5, the boundaries between the plurality of resonators 101 are represented by boundaries 105. As used herein, the term “first surface 106” of the resonator array structure 100 refers to the surface facing the internal space 36a of the pipe 36, and the term “second surface 107” is the surface facing the antenna 18. In other words, the resonator array structure 100 shown in FIG. 6 is arranged upside down in FIG. 2.

FIG. 7 shows an example of the plan-view and the cross section B-B of a single resonator according to the first embodiment. FIG. 7 shows the plan-view 150 of a single resonator 101 and the cross section 151 of the plan-view 150 taken along B-B line, in which one resonator 101 is used as an example among the plurality of resonators 101 formed integrally. As shown in the plan-view 150 and the cross section 151, the single resonator 101 is located within a region surrounded by a boundary 105. That is, in this embodiment, the resonator 101 has two C-shaped ring members 111 each surrounded by a dielectric body 112. The dielectric body 112 is formed so that the thickness 109a from the first C-shaped ring member 111 to the first surface 106 is smaller than the thickness 109b from the second C-shaped ring member 111 to the second surface 107. This allows the resonator array structure 100 to selectively generate plasma on the first surface 106 side, which is the inner space 36a side of the pipe 36. That is, the resonator array structure 100 can control the plasma generation surface by adjusting the thickness of the dielectric body 112 from each ring member 111 of the resonator 101 to the surface.

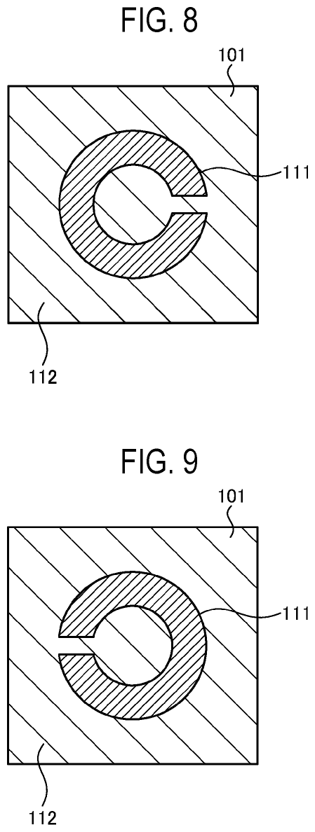

FIG. 8 is a cross-sectional view showing an example of the C-C cross section in FIG. 7. FIG. 9 is a cross-sectional view showing an example of the D-D cross section in FIG. 7. As shown in the cross-section 151 in FIG. 7, FIG. 8 and FIG. 9, the single resonator 101 has a structure in which two C-shaped ring members 111 made of conductors are arranged adjacent to each other so as to face in opposite directions, with the dielectric body 112 arranged between the ring members 111. That is, in the resonator 101, the dielectric body 112 is sandwiched between the two C-shaped ring members 111 facing opposite directions. Capacitor-equivalent elements are formed on the opposing surfaces of the two C-shaped ring members 111 and at both ends of each ring member 111, and coil-equivalent elements are formed along each ring member 111. This allows the resonator 101 to form a series resonant circuit. In the resonator 101 shown in FIGS. 7 to 9, the number of C-shaped ring members 111 arranged (hereinafter also appropriately referred to as the “number of layers”) is 2, but the number of layers of C-shaped ring members 111 may be greater than 2. In this case, the resonator 101 has a structure in which the C-shaped ring members 111 are arranged adjacent to each other in opposite directions, and the dielectric body 112 is arranged between the C-shaped ring members 111.

Referring again to FIG. 2, the controller 11 has a processor, a memory, and an input/output interface. The memory stores programs, process recipes, and the like. The processor reads a program from the memory and executes the program, thereby controlling each part of the apparatus body 10 via the input/output interface based on the process recipes stored in the memory.

For example, when plasma P is generated in the internal space 36a of the pipe 36, the controller 11 executes control so that the electromagnetic waves supplied to the internal space 36a by the antenna 18 resonate with the plurality of resonators 101 in a target frequency band that is higher than the resonance frequency of the plurality of resonators 101. Here, the resonance frequency is, for example, a frequency at which the transmission characteristic value (e.g., S21 value) of the plurality of resonators 101 becomes a minimum value.

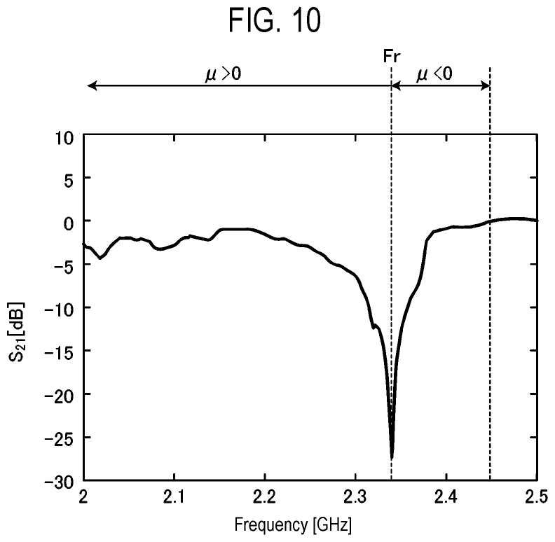

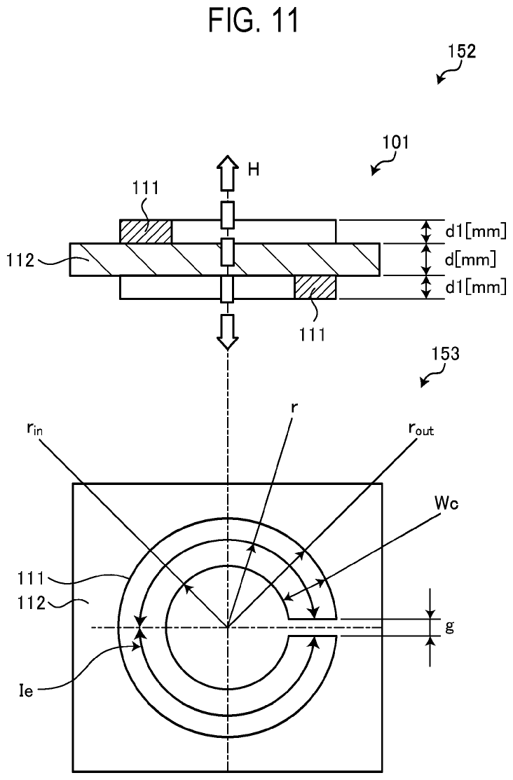

Now, the resonance frequency of the resonator 101 will be described using FIGS. 10 and 11. FIG. 10 is a diagram showing an example of the relationship between the S21 value of the resonator and the frequency of the electromagnetic wave. When the frequency of the electromagnetic waves supplied to the internal space 36a of the pipe 36 by the antenna 18 matches the resonance frequency Fr (approximately 2.35 GHZ) of each resonator 101, the S21 value of each resonator 101 becomes a minimum value, and resonance occurs between the electromagnetic waves and each resonator 101. While FIG. 10 uses microwaves as an example of the electromagnetic waves, the same applies to electromagnetic waves in a VHF band. Resonance between the electromagnetic waves and each resonator 101 is maintained even in a predetermined frequency band (e.g., approximately 0.1 GHZ) higher than the resonance frequency Fr of each resonator 101. In a predetermined frequency band higher than the resonance frequency Fr of each resonator 101, the electromagnetic waves resonate with each resonator 101, making both the permittivity and the permeability negative in the plasma generation region below the resonator array structure 100 in the internal space 36a. Accordingly, as can be seen from the above formula (1), electromagnetic waves can propagate in the plasma generation region below the resonator array structure 100 in the internal space 36a. The target frequency band is set to a predetermined frequency band (e.g., approximately 0.1 GHz) higher than the resonance frequency Fr of each resonator 101. The target frequency band is preferably, for example, within 0.05 times the resonance frequency Fr of each resonator 101.

FIG. 11 is an explanatory diagram showing an example of calculation of the resonance frequency of the resonator according to the first embodiment. As shown in the cross section 152 in FIG. 11, the resonator 101 may be considered to have a structure in which the dielectric body 112 is sandwiched between two C-shaped ring members 111. In this case, when a magnetic field H passing through the C-shaped ring member 111 of the resonator 101 is generated, an induced current Ie is generated in the C-shaped ring member 111. The dielectric body 112 surrounding the outside of the C-shaped ring member 111 is omitted in FIG. 11.

On the other hand, the resonance frequency of the resonator 101 can be calculated from the dimensions in the cross section 152 and the plan-view 153 in FIG. 11. That is, the resonance frequency of the resonator 101 can be calculated from the dimensions of the C-shaped ring member 111 and the thickness of the dielectric body 112 sandwiched between the two C-shaped ring members 111, as shown in the following formulas (2) to (5). Formula (2) is used to calculate the inductance L_{MA} of the resonator 101. Formula (3) is used to calculate the capacitance C_{half} of the capacitance CMA of the resonator 101, which corresponds to the upper or lower half of the plan-view 153. Formula (4) is used to calculate the capacitance CMA of the resonator 101. Formula (5) is used to calculate the resonance frequency Fr of the resonator 101.

$${L}_{MA} = {μ}_{0} r ( log ( 4 π ) - 1 ) \qquad ( 2 )$$

$${C}_{half} = {εε}_{0} \frac{S}{d} = {εε}_{0} \frac{( π ( {r}_{out}^{2} - {r}_{in}^{2} ) - {S}_{split} ) / 2}{{d}_{PTFE}} \qquad ( 3 )$$

$${C}_{MA} = \frac{1}{\frac{1}{{C}_{half}} + \frac{1}{{C}_{half}}} \qquad ( 4 )$$

$$Fr = \frac{1}{2 π \sqrt{{L}_{MA} {C}_{MA}}} \qquad ( 5 )$$

In formula (2), r represents the radius from the center of the C-shaped ring member 111 to the center of the width of the C, and μ₀ represents the magnetic permeability of vacuum. In formula (3), C_{half} represents the capacitance of the resonator 101 that corresponds to the upper or lower half of the plan-view 153. Furthermore, in formula (3), ε represents the permittivity, ε₀ represents the permittivity (electric constant) of vacuum, S represents the area of the upper or lower half of the C-shaped ring member 111, and d represents the distance between the two C-shaped ring members 111. Furthermore, in formula (3), rₒᵤₜ represents the outer radius of the C-shaped ring member 111, rᵢₙ represents the inner radius of the C-shaped ring member 111, and Sₛₚₗᵢₜ represents the area of the gap the C of the C-shaped ring member 111. Sₛₚₗᵢₜ can be approximately calculated as the area of a rectangle from the width Wc of the C-shaped ring member 111 and the gap g of the C shown in the plan-view 153. In addition, in formula (3), d_{PTFE} represents the distance between the two C-shaped ring members 111 when polytetrafluoroethylene (PTFE) is used as the dielectric body 112. As shown in the cross section 152, it is preferable that the thickness d1 of the two C-shaped ring members 111 be the same.

In formula (5), the resonance frequency Fr of the resonator 101 is calculated based on the inductance L_{MA} and capacitance C_{MA} calculated using formulas (2) and (4). The resonance frequency Fr decreases as the outer radius rₒᵤₜ and inner radius rᵢₙ of the C-shaped ring member 111 increase, and as the thickness d of the dielectric body 112 sandwiched between the two C-shaped ring members 111 decreases. The resonance frequency Fr also decreases as the number of layers of the C-shaped ring members 111 increases. In other words, by adjusting the outer radius rₒᵤₜ and inner radius rᵢₙ of the ring members 111 and the thickness d of the dielectric body 112, it is possible to form resonators 101 with different resonance frequencies. In this embodiment, the C-shaped ring member 111 is described as having the shape of a circular ring with a cutout at a portion thereof. However, the present disclosure is not limited thereto. The shape of the ring member is not limited to the circular ring shape, and may be, for example, the shape of an elliptical ring, a triangular ring, a square ring, a polygonal ring, or any other ring with a cutout (corresponding to the gap g) at a portion thereof. Furthermore, the dielectric constant & of the dielectric body 112 can be changed by changing the material. The material of the dielectric body 112 is not limited to PTFE, but may also be SiN, SiC, Al₂O₃, or the like.

As described above, in the resonator array structure 100 of this embodiment, the plurality of resonators 101 are arranged in a direction facing the opening of the antenna 18, so that the magnetic field H can pass through the C-shaped ring members 111 of the resonators 101 to make magnetic field resonance. Accordingly, each resonator 101 of the resonator array structure 100 can resonate at the resonance frequency Fr.

Regarding the propagation of electromagnetic waves through the plurality of resonators, the relationship between the resonance frequency and the refractive index, permittivity, and permeability has been reported, for example, by D. R. Smith, D. C. Vier, T. Koschny, and C. M. Soukoulis et al. in “Electromagnetic parameter retrieval from inhomogeneous metamaterials” in “PHYSICAL REVIEW E 71, 036617 (2005).”

Next, the generation of high-density radicals in the remote plasma source 30 of the plasma processing apparatus 1 will be described. As shown in FIG. 2, in the resonator array structure 100, the magnetic field H passes through each resonator 101, causing each resonator 101 to resonate, and exciting plasma P on the first surface 106 side of each resonator 101. That is, the first surface 106 side of the resonator array structure 100 serves as a plasma generation region. Since the processing gas is supplied from the gas supply 38 to the processing space S in the processing container 12, a flow toward the processing space S is generated in the internal space 36a of the pipe 36. Therefore, the processing gas supplied from the gas supply 38 to the internal space 36a excites plasma P on the first surface 106 side of each resonator 101, and flows into the processing space S through the through-holes 41a of the nozzle 41. The through-holes 41a of the nozzle 41 function as ion traps. That is, high-density radicals are supplied to the processing space S from the through-holes 41a of the nozzle 41. The workpiece WP is processed by the high-density radicals supplied to the processing space S.

As described above, in this embodiment, the high-density radicals can be generated while suppressing the influence of heat, electromagnetic waves, and ions. Specifically, the distance between the processing space S, where the workpiece WP is arranged, and the remote plasma source 30 is long so as to eliminate ions, which makes it possible to suppress charge-up damage caused by ions. Furthermore, the nozzle 41 separates the processing space S from the remote plasma source 30, thereby suppressing the thermal damage due to thermal radiation, the damage due to light, and the influence of electromagnetic waves. Furthermore, since the influence of heat, electromagnetic waves, and ions can be suppressed, it is possible to improve wettability during surface processing, which is suitable for thin-film formation (ALD: atomic layer deposition) and microfabrication (ALE: atomic layer etching). Furthermore, the long distance between the processing space S and the remote plasma source 30 allows the processing gas and radicals to mix evenly, thereby enabling uniform processing of the workpiece WP. The position of introduction of the radical-containing activated gas into the processing container 12 can be selected arbitrarily. Furthermore, the resonator array structure 100 generates high-density plasma, resulting in efficient radical generation and improved substrate processing rate. In addition, since the cleaning gas spreads more widely within the processing container 12, deposits adhering to the sidewall 12a of the processing container 12 can be cleaned.

### Modification 1

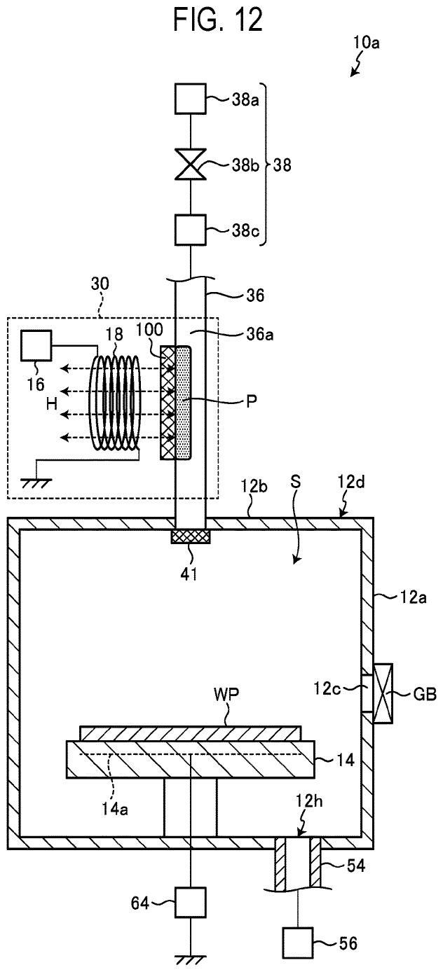

Next, Modifications 1 to 6 of the first embodiment will be described using FIGS. 12 to 26. In each of the modifications described below, the same components as those of the apparatus body 10 of the first embodiment are designated by like reference numerals, and descriptions of overlapping components and operations will be omitted. FIG. 12 is a schematic cross-sectional view showing an example of the configuration of a plasma processing apparatus according to Modification 1. The apparatus body 10a of Modification 1 shown in FIG. 12 is different from the apparatus body 10 of the first embodiment in that the arrangement position of the pipe 36 is changed to the upper surface 12b of the processing container 12d. In the apparatus body 10a, for example, the pipe 36 is connected to the processing container 12d so that the nozzle 41 is in contact with the center of the upper surface 12b. In the example of FIG. 12, the arrangement position of the resonator array structure 100 is changed to the upper portion of the processing container 12d in accordance with the change in the arrangement position of the pipe 36. However, the positional relationship between the resonator array structure 100 and the pipe 36 remains unchanged, and the resonator array structure 100 is provided on the side of the pipe 36. The nozzle 41 may also be, for example, a shower plate having a diameter similar to that of the stage 14. In this manner, in the apparatus body 10a, the upper surface 12b faces the upper surface of the workpiece WP mounted on the stage 14, thereby further improving the in-plane uniformity of the workpiece WP.

### Modification 2

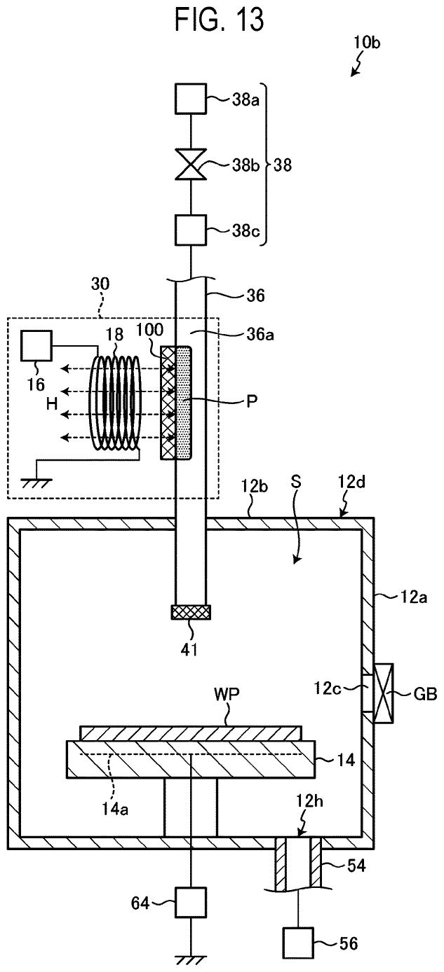

FIG. 13 is a schematic cross-sectional view showing an example of the configuration of a plasma processing apparatus according to Modification 2. In the apparatus body 10b of Modification 2 shown in FIG. 13, the amount of protrusion of the pipe 36 into the processing container 12d is increased compared to the apparatus body 10a of Modification 1, and the nozzle 41 is arranged closer to the stage 14. In this way, the apparatus body 10b can improve the density of radicals near the workpiece WP more than the apparatus body 10a of Modification 1.

### Modification 3

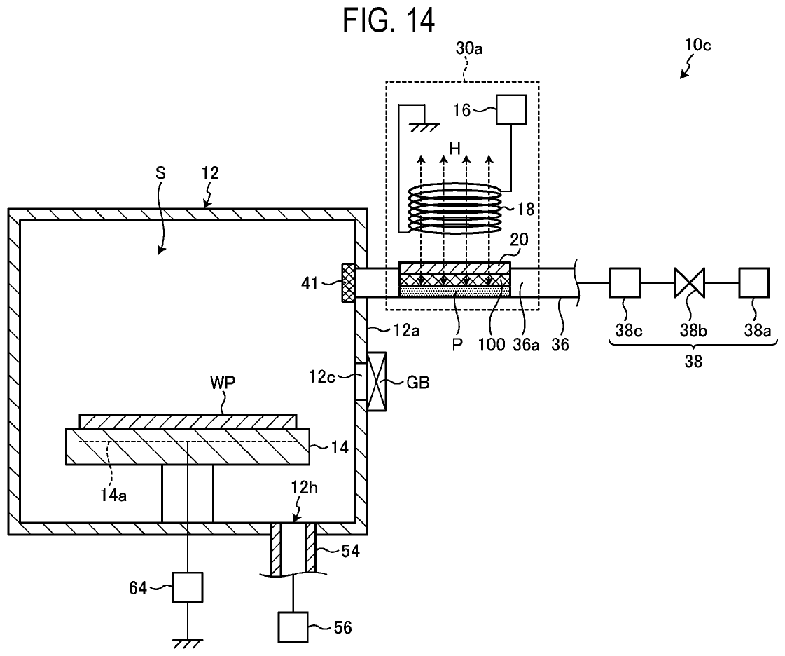

FIG. 14 is a schematic cross-sectional view showing an example of the configuration of a plasma processing apparatus according to Modification 3. The apparatus body 10c of Modification 3 shown in FIG. 14 is different from the apparatus body 10 of the first embodiment in that a dielectric window 20 is provided on the sidewall of the pipe 36 in addition to the resonator array structure 100, thereby forming a remote plasma source 30a. In this way, in the remote plasma source 30a, the resonator array structure 100 is arranged in the internal space 36a of the pipe 36, so that the width of the resonator array structure 100 in the cross-sectional direction of the pipe 36 can be made wider than that in the first embodiment. In other words, the generation area of the plasma P can be made larger, and the density of radicals supplied to the processing space S can be further improved.

### Modification 4

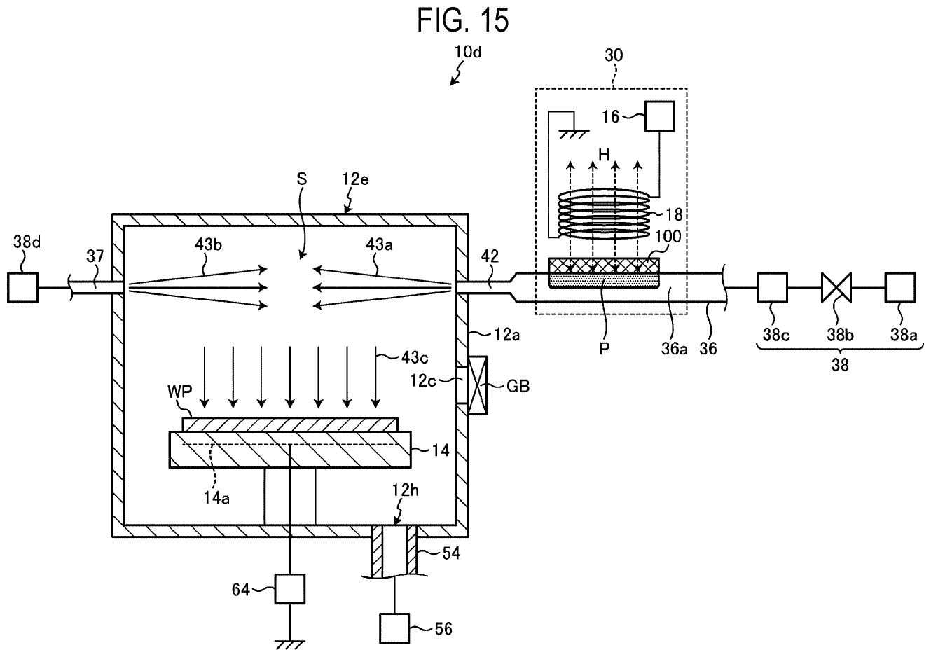

FIG. 15 is a schematic cross-sectional view showing an example of the configuration of a plasma processing apparatus according to Modification 4. The apparatus body 10d of Modification 4 shown in FIG. 15 further includes a pipe 37 and a gas supply 38d that introduce another processing gas into the processing container 12e, in addition to the components of the apparatus body 10 of the first embodiment. The apparatus body 10d also includes an orifice 42 instead of the nozzle 41 on the processing container 12e side of the pipe 36. The orifice 42 functions as an ion trap that eliminates ions depending on its length, in place of the nozzle 41. The orifice 42 is an example of a gas injector. The pipe 37 also includes an orifice similar to the orifice 42, for example, on the processing container 12e side of the pipe 37. In the apparatus body 10d, the processing gas (carrier gas) supplied from the gas supply 38 is activated by the plasma P generated by the resonator array structure 100 and is supplied to the processing space S from the orifice 42 as an activated gas 43a. Furthermore, a processing gas 43b is supplied to the processing space S from the gas supply 38d and the pipe 37. The activated gas 43a and the processing gas 43b are mixed in the processing space S, and the processing gas 43b is activated by the activated gas 43a to become a processing gas 43c, which is supplied to the upper surface of the workpiece WP. In this way, in the apparatus body 10d, a processing gas different from the plasma-excited processing gas can be supplied to the processing space S and can be activated.

### Modification 5

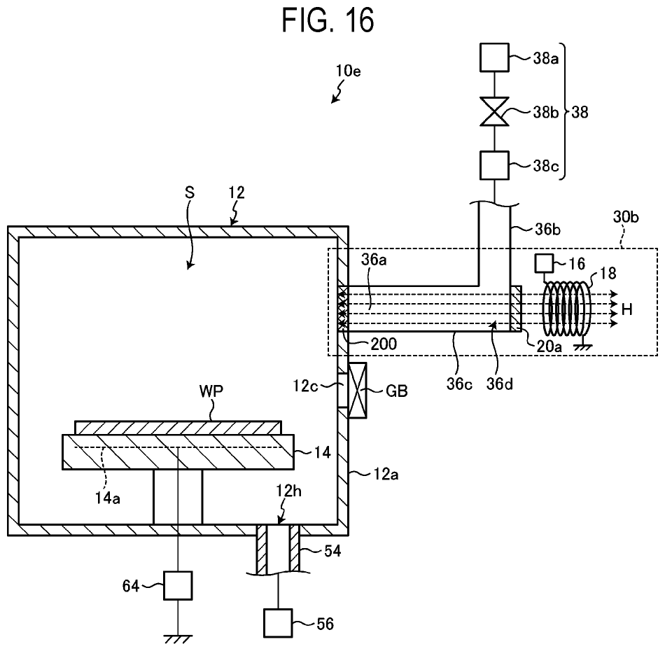

FIG. 16 is a schematic cross-sectional view showing an example of the configuration of a plasma processing apparatus according to Modification 5. As compared to the apparatus body 10 of the first embodiment, the apparatus body 10e of Modification 5 shown in FIG. 16 is configured by integrating the nozzle 41 and the resonator array structure 100 into a resonator array structure 200. The resonator array structure 200 is provided on the processing container 12 side of the pipe 36c so as to block the cross section of the pipe 36c. The apparatus body 10e also has pipes 36b and 36c instead of the pipe 36. Furthermore, a dielectric window 20a is provided at a connection portion 36d between the pipe 36b and the pipe 36c, and an antenna 18 is arranged so as to be able to supply a magnetic field H to the resonator array structure 200 via the dielectric window 20a and the internal space 36a. In other words, the apparatus body 10e includes a remote plasma source 30b instead of the remote plasma source 30.

The pipes 36b and 36c are connected to each other at the connection portion 36d, for example, at a right angle. In the connection portion 36d, a dielectric window 20a is provided on the wall surface facing the plane of the resonator array structure 200 when viewed from the antenna 18 side. The pipes 36b and 36c may be connected at any angle as long as the magnetic field H from the antenna 18 can be supplied to the resonator array structure 200 through the dielectric window 20a.

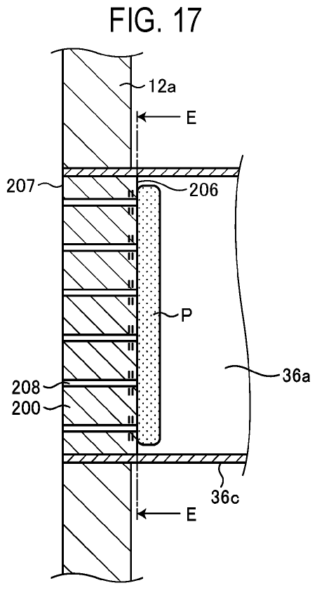

FIG. 17 is a view showing an example of a cross section near the resonator array structure according to Modification 5. As shown in FIG. 17, the resonator array structure 200 is, for example, a flat resonator array structure similar to the resonator array structure 100 of the first embodiment. The resonator array structure 200 is provided at the end of the pipe 36c and has a thickness similar to that of the sidewall 12a. In FIG. 17, the thicknesses are depicted as different to illustrate the cross section E-E. In the resonator array structure 200, plasma P is generated on the first surface 206 side. The plasma P generated on the first surface 206 side is supplied to the second surface 207 side of the resonator array structure 200, i.e., the processing space S, through through-holes 208 provided at the centers of the resonators 201 (described later). At this time, ions in the plasma P are recombined through the through-holes 208 and supplied to the processing space S as radicals. Here, the first surface 206 of the resonator array structure 200 is the surface facing the internal space 36a, i.e., the antenna 18 and dielectric window 20a, and the second surface 207 is the surface facing the processing space S.

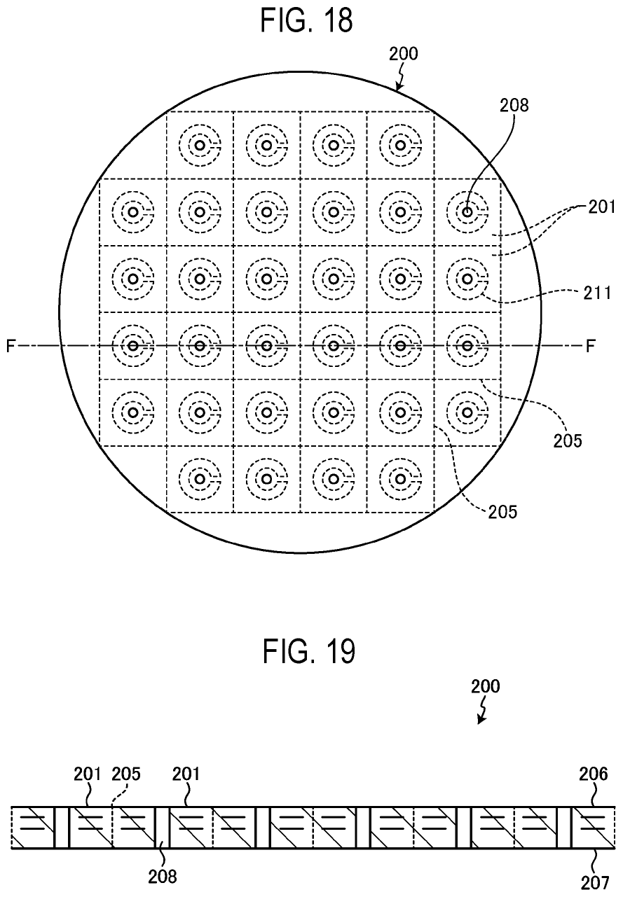

Now, the detailed configuration of the resonator array structure 200 will be described with reference to FIG. 18. FIG. 18 is a plan view showing an example of the configuration of the resonator array structure according to Modification 5, as seen from the upstream direction of the pipe. FIG. 18 shows the E-E cross section of the resonator array structure 200 as seen from the internal space 36a side in FIG. 17, i.e., from the antenna 18 and dielectric window 20a side. The resonator array structure 200 is, for example, arranged so that its longitudinal direction coincides with (is parallel to) the cross-sectional direction of the pipe 36c. In Modification 5, plasma P is generated on the internal space 36a side of the pipe 36c of the resonator array structure 200.

The resonator array structure 200 is formed by arranging a plurality of resonators 201 in a lattice pattern. Each of the resonators 201 can resonate with the magnetic field component of electromagnetic waves and has a size smaller than the wavelength of the electromagnetic waves. The resonators 201 may also be described as being arranged in a direction of a plane parallel to the first surface 206 of the resonator array structure 200 on which a base has a larger area, i.e., in a coplanar direction. Specifically, as shown in FIG. 18, the resonators 201 are arranged in a direction of a plane parallel to the cross-sectional direction of the pipe 36c in the flat resonator array structure 200. In other words, when viewed from the antenna 18 side, the C-shaped ring members 211, which are shown transparently, are arranged in a lattice pattern so that the C shape is visible. The resonator array structure 200 is arranged, for example, in six rows and six columns, with one of each corner omitted. In other words, the resonator array structure 200 includes, for example, eight resonators 201 arranged in each quadrant. In this case, the boundaries between the plurality of resonators 201 are shown as boundaries 205, but in reality, the plurality of resonators 201 are integrally formed as the resonator array structure 200. The plurality of resonators 201 may be formed separately and fitted into a lattice-shaped frame or glued together to form the resonator array structure 200. Each of the plurality of resonators 201 forms a series resonant circuit consisting of a capacitor-equivalent element and a coil-equivalent element. The series resonant circuit is realized by patterning a conductor on a plane. The magnetic field H generated by the antenna 18 is directed to pass through the C-shaped ring member 211.

FIG. 19 is a cross-sectional view showing an example of the F-F cross section in FIG. 18. As shown in FIG. 19, in the F-F cross section of the resonator array structure 200, the cross sections of the plurality of resonators 201 appear side by side. Similar to FIG. 18, the boundaries of the plurality of resonators 201 are represented by boundaries 205. As described above, the first surface 206 of the resonator array structure 200 faces the internal space 36a, i.e., faces the antenna 18 and the dielectric window 20a, and the second surface 207 faces the processing space S. In addition, a through-hole 208 is provided at the center of each of the plurality of resonators 201.

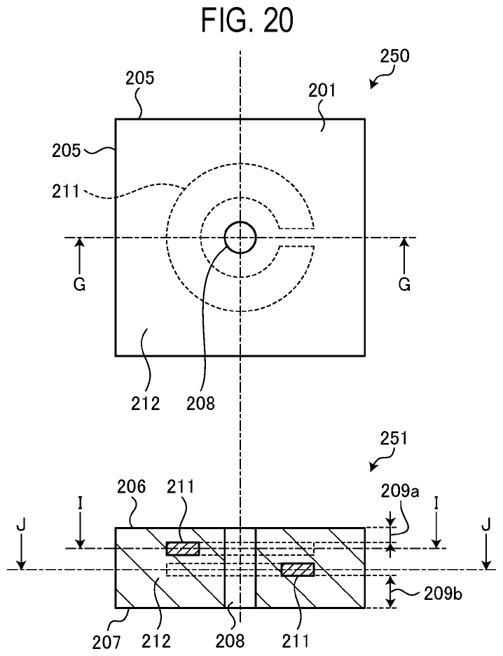

FIG. 20 shows an example of a plan-view and a G-G cross section of a single resonator according to Modification 5. FIG. 20 shows a plan-view 250 of a single resonator 201 and a cross section 251 of the plan-view 250 taken along line G-G, in which one resonator 201 is used as an example among the plurality of resonators 201 formed integrally. As shown in the plan-view 250 and the cross section 251, the single resonator 201 is located within a region surrounded by a boundary 205. That is, in Modification 5, the resonator 201 has two C-shaped ring members 211 each surrounded by a dielectric body 212. The dielectric body 212 is formed so that the thickness 209a from the first C-shaped ring member 211 to the first surface 206 is smaller than the thickness 209b from the second C-shaped ring member 211 to the second surface 207. As a result, in the resonator array structure 200, plasma can be selectively generated on the first surface 206 side, which is the inner space 36a side of the pipe 36c, just like the resonator array structure 100. That is, in the resonator array structure 200, the plasma generation surface can be controlled by the thickness of the dielectric body 212 from each ring member 211 of the resonator 201 to the surface.

The through-hole 208 brings the internal space 36a faced by the first surface 206 into communication with the processing space S faced by the second surface 207. The through-hole 208 has, for example, a circular cross section. The through-hole 208 has, for example, a diameter of 10 mm or less, which allows ions to recombine and allows radicals and inactivated processing gases to pass from the internal space 36a of the pipe 36c to the processing space S. The through-hole 208 more preferably has a diameter of, for example, 2 mm or less. That is, the through-hole 208 has a diameter that does not allow ions to pass from the internal space 36a to the processing space S. That is, radicals and inactivated processing gases contained in the plasma generated in the internal space 36a on the first surface 206 side are supplied to the processing space S on the second surface 207 side through the through-hole 208. Ions contained in the plasma are recombined to form radicals as they pass through the through-hole 208, and are similarly supplied to the processing space S. High-density radicals are supplied to the processing space S, and the workpiece WP is processed by the radicals.

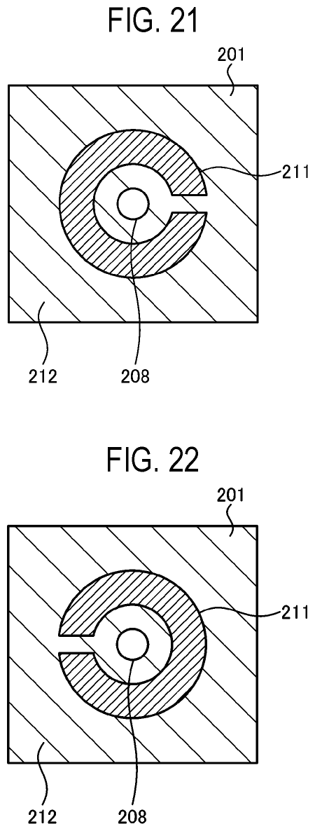

FIG. 21 is a cross-sectional view showing an example of the I-I cross section in FIG. 20. FIG. 22 is a cross-sectional view showing an example of the J-J cross section in FIG. 20. As shown in the cross section 251 of FIG. 20, FIG. 21 and FIG. 22, the single resonator 201 has a structure in which two C-shaped ring members 211 made of conductors are arranged adjacent to each other so as to face in opposite directions, with the dielectric body 212 arranged between the ring members 211. That is, in the resonator 201, the dielectric body 212 is sandwiched between the two C-shaped ring members 211 facing opposite directions. Furthermore, as described above, the through-hole 208 is provided at the center of the two C-shaped ring members 211. Capacitor-equivalent elements are formed on the opposing surfaces of the two C-shaped ring members 211 and at both ends of each ring member 211, and coil-equivalent elements are formed along each ring member 211. This allows the resonator 201 to form a series resonant circuit. In the resonator 201 shown in FIGS. 20 to 22, the number of layers of the C-shaped ring member 211 is two, but the number of layers of the C-shaped ring member 211 may be more than two. In this case, the resonator 201 has a structure in which the C-shaped ring members 211 are arranged adjacent to each other in opposite directions and in which a dielectric body 212 is arranged between the C-shaped ring members 211. The resonance frequency of the resonator 201 is the same as that of the resonator 101 of the first embodiment, and therefore the description thereof will be omitted.

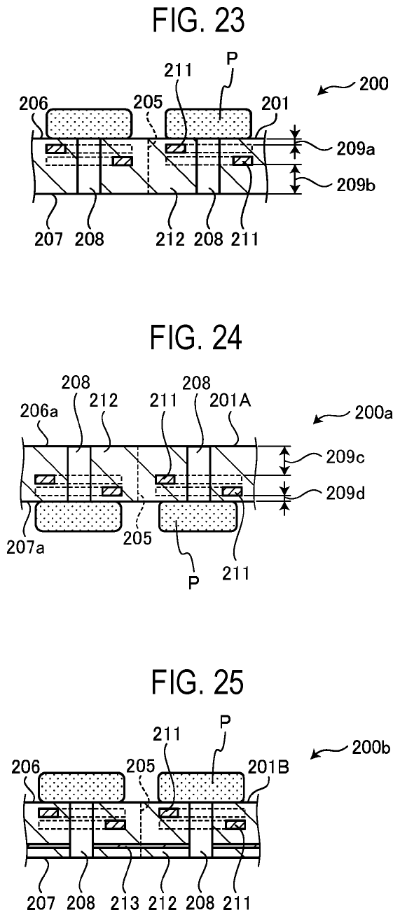

Now, the relationship between the position of the ring member and the plasma generation region will be described using the resonator array structure 200 as an example. FIGS. 23 and 24 are views showing an example of the relationship between the position of the ring member and the plasma generation region. As shown in FIG. 23, in the resonator array structure 200, the thickness 209a of the dielectric body 212 from the first C-shaped ring member 211 to the first surface 206 is smaller than the thickness 209b of the second C-shaped ring member 211 to the second surface 207. The smaller the thickness of the dielectric body 212 from the C-shaped ring member 211 to the surface, the more easily it absorbs the power of electromagnetic waves. Plasma is more easily excited on the surface on the thinner side of the dielectric body 212 of each resonator 201. For example, in the resonator array structure 200, by making the thickness 209b at least twice the thickness 209a, plasma is more easily excited on the first surface 206 side, i.e., on the thickness 209a side of each resonator 201.

On the other hand, in the resonator array structure 200a shown in FIG. 24, the thickness 209c of the dielectric body 212 from the first C-shaped ring member 211 to the first surface 206a is larger than the thickness 209d from the second C-shaped ring member 211 to the second surface 207a. In this case, by making the thickness 209c at least twice the thickness 209d, plasma is more likely to be excited on the second surface 207a side of each resonator 201A, i.e., on the thickness 209d side. If the thicknesses 209c and 209d are substantially the same, plasma is excited on both the first surface 206a and the second surface 207a side. As shown in FIGS. 23 and 24, the plasma generation surface can be controlled by the position of the C-shaped ring member 211 within the resonator 201. In Modification 5, radicals are supplied to the processing space S. Therefore, the resonator array structure 200 shown in FIG. 23, in which the first surface 206 of the plasma generation surface is located on the internal space 36a side, is preferred.

FIG. 25 is a view showing an example of the relationship between the position of the shield and the plasma generation region. The resonator array structure 200b shown in FIG. 25 further includes a shield 213 between the second C-shaped ring member 211 of the resonator array structure 200 and the second surface 207. The shield 213 is a conductive member made of aluminum or the like, and forms a Faraday shield. The shield 213 shields the electromagnetic waves radiated by the antenna 18 from the electric field toward the second surface 207 of the resonator array structure 200b. Since there is no electric field on the second surface 207 side of the resonator array structure 200b, no voltage is applied. This suppresses plasma excitation and discharge on the second surface 207 side of the resonator array structure 200b, i.e., on the processing space S side.

As described above, in Modification 5, by using the flat resonator array structure 200, the nozzle 41 can be omitted. Furthermore, in Modification 5, the distance between the plasma generation region of the resonator array structure 200 and the processing space S is shorter than that in the first embodiment, so that radicals can be supplied at a higher density. Furthermore, the length of the pipe 36c is not limited as long as it is long enough to supply the magnetic field H from the antenna 18 to the resonator array structure 200, which improves the degree of freedom in arranging the remote plasma source 30b.

### Modification 6

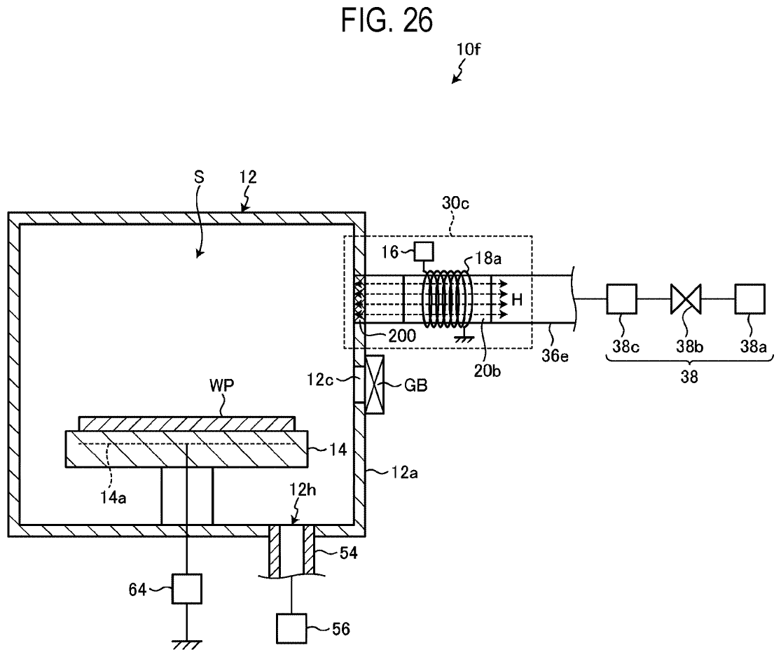

FIG. 26 is a schematic cross-sectional view showing an example of the configuration of a plasma processing apparatus according to Modification 6. The apparatus body 10f of Modification 6 shown in FIG. 26 includes an antenna 18a, a dielectric window 20b, and a pipe 36e instead of the antenna 18, the dielectric window 20a, and the pipes 36b and 36c of the apparatus body 10e of Modification 5. The RF power source 16, the antenna 18a, the dielectric window 20b, and the resonator array structure 200 form a remote plasma source 30c. In the apparatus body 10f, the wall surface in the circumferential direction of the cross section of a portion of the pipe 36e is the dielectric window 20b, and the coil of the antenna 18a is wound around the dielectric window 20b. In other words, the dielectric window 20b and the internal space of the pipe 36e are located inside the coil of the antenna 18a. The magnetic field H generated by the antenna 18a passes through the pipe 36e via the dielectric window 20b and is supplied to the resonator array structure 200. In this way, in the remote plasma source 30c, the antenna 18a is arranged so as to surround the dielectric window 20b of the pipe 36e, which further improves the degree of freedom in arranging the remote plasma source 30c.

### Second Embodiment

In the first embodiment described above, the flat resonator array structures 100 and 200 are used, but a cellular resonator array structure in which each resonator forms a plurality of cells may also be used. An embodiment in this case will be described as a second embodiment. The plasma processing apparatus 2 according to the second embodiment is the same as that of the first embodiment described above except for the configuration of the remote plasma source, and therefore the descriptions of the overlapping configurations and operations will be omitted.

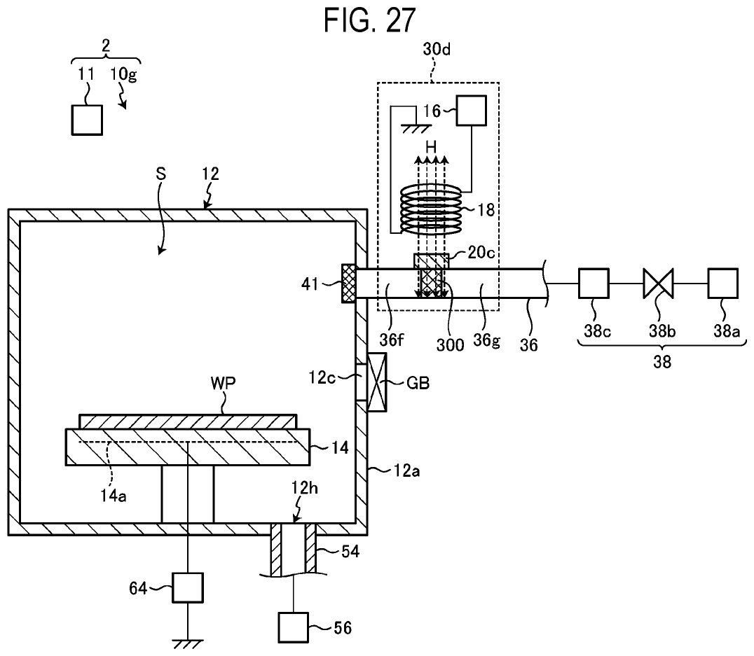

FIG. 27 is a schematic cross-sectional view showing an example of the configuration of the plasma processing apparatus according to the second embodiment. As shown in FIG. 27, the apparatus body 10g according to the second embodiment includes a remote plasma source 30d instead of the remote plasma source 30 of the first embodiment. The remote plasma source 30d includes an RF power source 16, an antenna 18, a dielectric window 20c, and a resonator array structure 300 arranged in a pipe 36. The remote plasma source 30d may include a gas supply 38, as in the first embodiment.

The dielectric window 20c is provided on the sidewall of the pipe 36, just like the dielectric window 20 of Modification 3. The size of the dielectric window 20c is not limited as long as it is large enough to supply the magnetic field H to the resonator array structure 300.

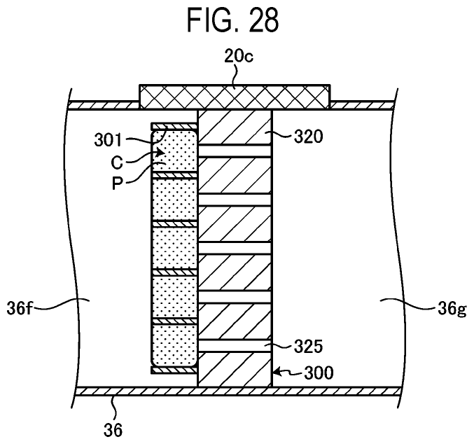

FIG. 28 is a view showing an example of a cross section near the resonator array structure according to the second embodiment. As shown in FIG. 28, the resonator array structure 300 is arranged at a position where the dielectric window 20c of the pipe 36 is located, so that a base plate 320 (described later) is parallel to the cross-sectional direction of the pipe 36. In the resonator array structure 300, a processing gas flows from the internal space 36g toward the internal space 36f through a through-hole 325 of each cell C provided in the base plate 320. In the cell space of each cell C on the internal space 36f side, the processing gas is plasma-excited to generate plasma P. The plasma P generated in each cell C is supplied to the processing space S via the internal space 36f and the nozzle 41. Ions in the plasma P are recombined through the through-holes 41a of the nozzle 41 and supplied to the processing space S as radicals.

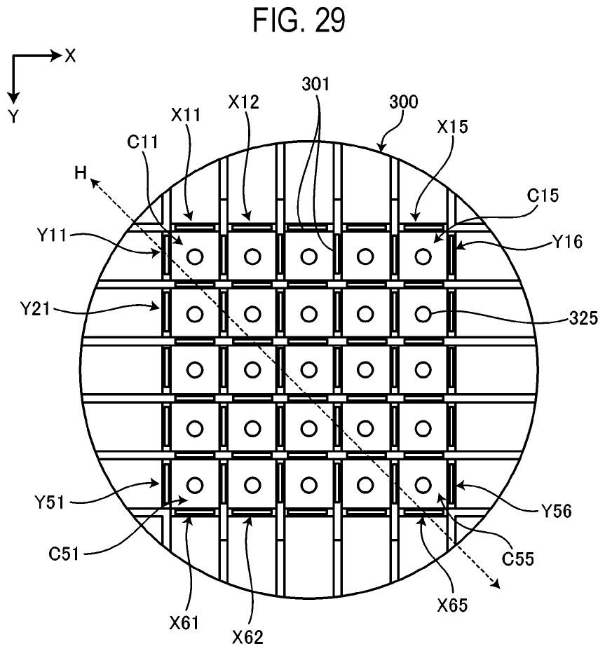

FIG. 29 is a plan view showing an example of the configuration of a resonator array structure according to the second embodiment as seen from the downstream direction of the pipe. The resonator array structure 300 shown in FIG. 29 is seen from the downstream direction of the pipe 36, i.e., from the nozzle 41 side. That is, the resonator array structure 300 is arranged so that its first surface is parallel to the cross-sectional direction of the pipe 36. In the following description, the resonator array structure 300 will be described based on the X-axis direction and the Y-axis direction in FIG. 29.

As shown in FIG. 29, the resonator array structure 300 includes card-shaped resonators 301 arranged in a lattice pattern. In the following description, the resonator array structure 300 may be referred to as a metamaterial 300, and the card-shaped resonators 301 may be referred to as metaatoms 301. In the example of FIG. 29, the metaatoms 301 are arranged so that cells C surrounded by the metaatoms 301 form five columns in the X-axis direction and five rows in the Y-axis direction (cells C11 to C55). That is, the metaatoms 301 are arranged in six rows and five columns, such as X11, X12, . . . , X15, . . . , X61, X62, . . . , X65, with their longitudinal directions aligned with the X-axis direction. Furthermore, the metaatoms 301 are arranged in five rows and six columns, such as Y11, Y21, . . . , Y51, . . . , Y16, Y26, . . . , Y56, with their longitudinal directions aligned with the Y-axis direction. The lattice opening and depth of cell C are equal to or larger than the outer shape of the C-shaped ring member (e.g., ring member 311B) of metaatom 301. In other words, the metaatom 301 can also be expressed as being arranged in a direction of a plane perpendicular to the first surface of the metamaterial 300 on which a base has a larger area, i.e., in a coplanar direction for each of the X-axis direction and the Y-axis direction.

Furthermore, a through-hole 325 is formed at the center of the bottom surface of each cell C of the resonator array structure 300. The metaatoms 301 constituting the peripheral cells C and the metaatoms 301 near the central cell C may have different resonance frequencies Fr. In the second embodiment, the direction of the magnetic field His, for example, a direction in which the magnetic field H passes through each of the metaatoms 301 arranged in both the X-axis direction and the Y-axis direction to constitute each cell C. The direction of the magnetic field H may be either the X-axis direction or the Y-axis direction. In this case, the metaatom 301 in which the magnetic field H passes through the C-shaped ring member 311 of the metaatom 301 resonate with the magnetic field H.

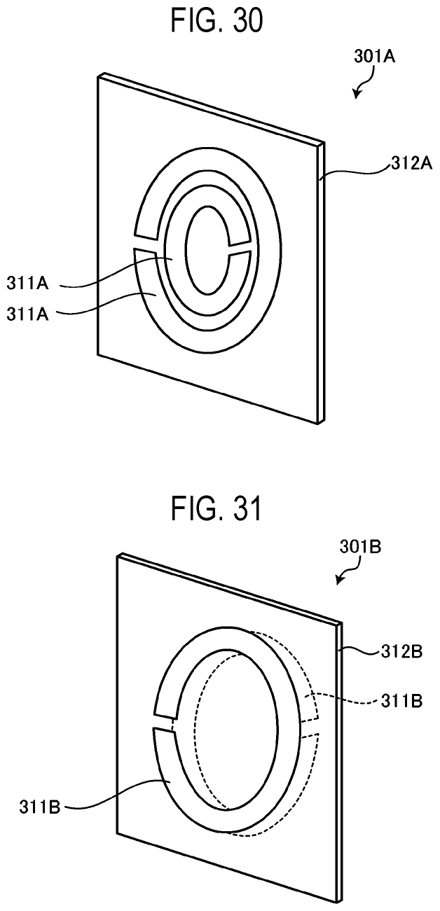

The plurality of resonators 301 includes at least one of resonators 301A and 301B shown in FIGS. 30 and 31. Each of the plurality of resonators 301 forms a series resonant circuit made up of a capacitor-equivalent element and a coil-equivalent element. The series resonant circuit is realized by patterning a conductor on a plane.

FIG. 30 is a view showing an example of the configuration of the card-shaped resonator according to the second embodiment. The card-shaped resonator 301A shown in FIG. 30 has a structure in which two C-shaped, concentric, conductor ring members 311A are stacked on one surface of a dielectric plate 312A. Capacitor-equivalent elements are formed on the opposing surfaces of the inner and outer ring members 311A and at both ends of each ring member 311A, and coil-equivalent elements are formed along each ring member 311A. This allows the resonator 301A to form a series resonant circuit.

FIG. 31 is a view showing an example of the configuration of the card-shaped resonator according to the second embodiment. The card-shaped resonator 301B shown in FIG. 31 has a structure in which a dielectric plate 312B is arranged between two C-shaped ring members 311B made of a conductor and arranged adjacent to each other in opposite directions. That is, in the resonator 301B, the dielectric plate 312B is sandwiched between the two C-shaped ring members 311B arranged in opposite directions. Capacitor-equivalent elements are formed on the opposing surfaces of the two C-shaped ring members 311B and on both ends of each ring member 311B, and coil-equivalent elements are formed along each ring member 311B. This allows the resonator 301B to form a series resonant circuit. The card-shaped resonator 301B may also be expressed as a card-shaped configuration for each pair of two C-shaped ring members 311B.

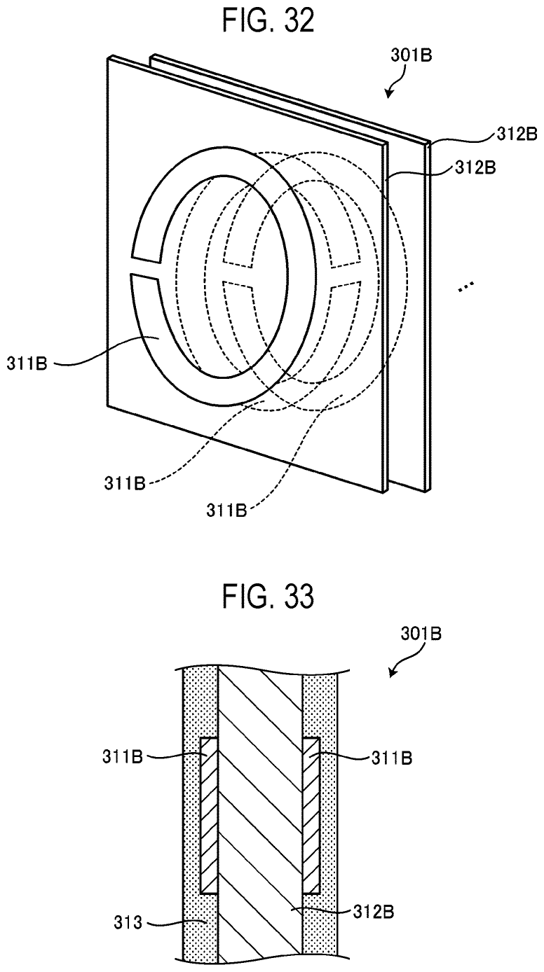

In the resonator 301B shown in FIG. 31, the “number of layers” of the ring member 311B is two, but the number of layers of the ring member 311B may be greater than two. FIG. 32 is a view showing another example of the configuration of the card-shaped resonator according to the second embodiment. The resonator 301B shown in FIG. 32 has N (N≥2) C-shaped ring members 311B made of conductors, and a dielectric plate 312B is arranged between the ring members 311B arranged adjacent to each other in opposite directions. Even with this structure, the resonator 301B can form a series resonant circuit. In the following description, when the resonator 301A and the resonator 301B are referred to as the resonators 301, the ring members 311A and 311B may be referred to as the ring members 311, and the dielectric plates 312A and 312B may be referred to as the dielectric bodies 312.

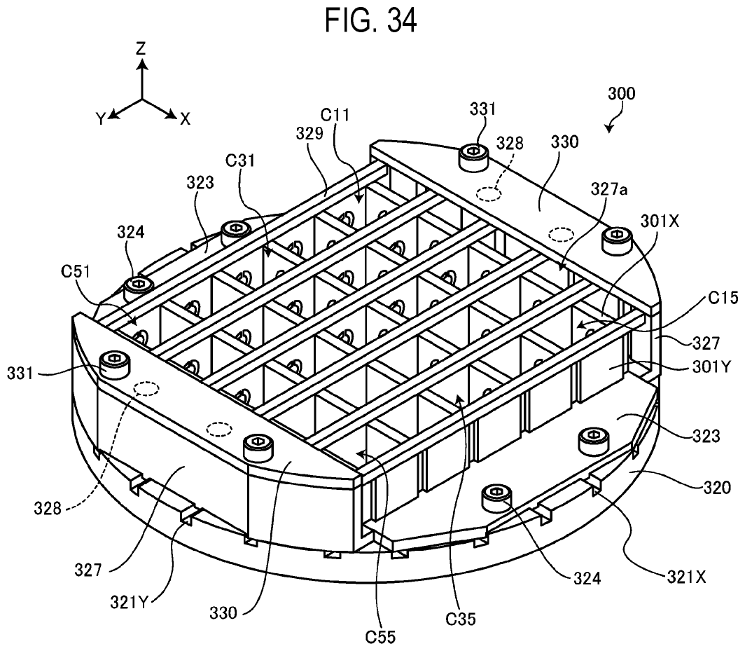

Furthermore, an insulating coating may be formed on each of the plurality of resonators 301. FIG. 33 is a view showing an example of the cross section of the card-shaped resonator according to the second embodiment. FIG. 33 shows a side cross section of the resonator 301B shown in FIG. 31. An insulating coating (an example of a dielectric film) 313 is formed on the surface of the resonator 301B. The material of the coating 313 is, for example, ceramic. The thickness of the coating 313 is, for example, in the range of 0.001 mm to 2 mm. By forming the insulating coating 313 on each of the plurality of resonators 301, abnormal discharge in each of the plurality of resonators 301 can be suppressed.

FIG. 34 is a perspective view showing an example of the resonator array structure according to the second embodiment. In FIG. 34, the ring members are drawn on some of the metaatoms 301 to make the orientation of the metaatoms 301 easier to understand, but in reality, the surfaces thereof are covered with a dielectric body (insulating film).

The resonator array structure 300 shown in FIG. 34 includes a base plate 320. The base plate 320 is made of a dielectric material such as quartz or ceramics. The base plate 320 is provided with a plurality of grooves 321X extending in the X-axis direction and a plurality of grooves 321Y extending in the Y-axis direction, as grooves into which the metaatoms 301 are fitted. In addition, as shown in FIG. 29, a through-hole 325 is provided in the portion of the base plate 320 that serves as the bottom surface of each cell.

A metaatom 301 is fitted into each of the grooves 321X and 321Y. In the following description, the metaatom 301 fitted into the groove 321X may be referred to as a metaatom 301X, and the metaatom 301 fitted into the groove 321Y may be referred to as a metaatom 301Y. Furthermore, the metaatom 301X is assumed to be wider than the metaatom 301Y, and the ends of the metaatoms 301X are assumed to be in contact with each other. Each of the regions surrounded by the metaatom 301X and the metaatom 301Y is the cell C. In the example of FIG. 34, five rows and five columns of cells consisting of cells C11 to C55 are formed.

The side pressing members 323 are fixed to the base plate 320 using screws 324 so as to contact one side of the meta atoms 301Y at locations Y11 to Y51 and locations Y16 to Y56 shown in FIG. 29 among the outermost metaatoms 301. The side pressing members 323 and the screws 324 are an example of pressing members, and are made of ceramics such as alumina, which is a dielectric material.

The side pressing members 327 are fixed to the base plate 320 using screws 328 so as to contact one side of the metaatoms 301X at locations X11 to X15 and X61 to X65 shown in FIG. 29 among the outermost metaatoms 301. A space 327a is formed between the side pressing members 327 and the outermost metaatom 301X. The space 327a is provided in consideration of plasma generation, but it may be omitted. The side pressing members 327 may directly contact one side of the metaatom 301X. The side pressing members 327 and the screws 328 are an example of pressing members and are made of ceramics such as alumina, which is a dielectric material.

A pressing member 329 presses the metaatoms 301X and 301Y between the two side pressing members 327. The pressing member 329 is installed between the two side pressing members 327 so as to press continuously the upper portion of the metaatom 301Y in the longitudinal direction and also press the upper end of the metaatom 301X. In other words, the pressing member 329 is installed parallel to the side pressing members 323. The pressing member 329 is made of ceramics such as alumina, which is a dielectric material.

A member 330 is arranged above the side pressing member 327 in order to secure the pressing member 329. An end of the pressing member 329 is sandwiched between the side pressing member 327 and the member 330. The member 330 is fixed to the side pressing member 327 with screws 331. The member 330 and the screw 331 are an example of the pressing member, and are made of ceramics such as alumina, which is a dielectric material.

The through-hole 325 brings the internal space 36f of the pipe 36 facing each cell C into communication with the internal space 36g of the pipe 36 facing the surface of the base plate 320 opposite to the surface on which each cell C is formed, i.e., the lower surface of the base plate 320. That is, in FIG. 27, the processing gas flowing from the gas supply 38 on the upstream side of the pipe 36 toward the processing space S can pass through the through-hole 325. The through-hole 325 has, for example, a circular cross section. The resonator array structure 300 may have a structure in which the base plate 320 is omitted and the respective resonators 301 are connected by, for example, welding.

Next, the generation of high-density radicals in the remote plasma source 30d of the plasma processing apparatus 2 will be described. As shown in FIGS. 27 and 28, in the resonator array structure 300, the magnetic field H is directed to pass through the resonators 301 of each cell C, causing the resonators 301 to resonate and exciting plasma P in each cell C. That is, the cell space of each cell C serves as a plasma generation region. Since the processing gas is supplied from the gas supply 38 to the processing space S, a flow toward the processing space S is generated in the internal space 36f of the pipe 36. Accordingly, the processing gas supplied from the gas supply 38 to the internal space 36f through the through-hole 325 excites plasma P in each cell C and flows into the processing space S through the through-holes 41a of the nozzle 41. The through-holes 41a of the nozzle 41 function as ion traps. That is, high-density radicals are supplied from the through-holes 41a of the nozzle 41 to the processing space S. The workpiece WP is processed by the high-density radicals supplied to the processing space S.

Even when the cell-shaped resonator array structure 300 is used as described above, high-density radicals can be generated while suppressing the influence of heat, electromagnetic waves, and ions, as in the first embodiment.

### Modification 7

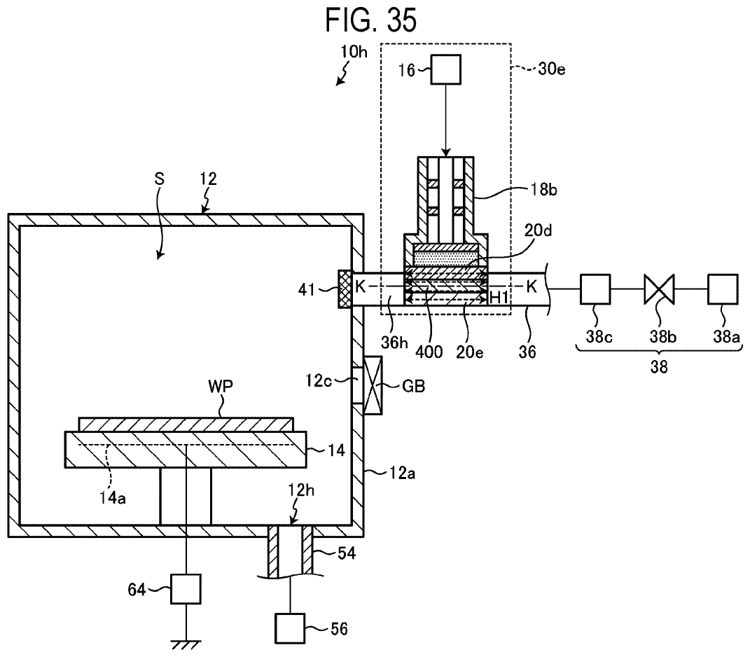

Next, Modifications 7 and 8 of the second embodiment will be described using FIGS. 35 to 39. In each of the modifications described below, the same components as those of the apparatus bodies 10 and 10g of the first and second embodiments are designated by like reference numerals, and the descriptions of the same components and operations will be omitted. FIG. 35 is a schematic cross-sectional view showing an example of the configuration of a plasma processing apparatus according to Modification 7. The apparatus body 10h of Modification 7 shown in FIG. 35 includes a remote plasma source 30e instead of the remote plasma source 30d of the second embodiment. The remote plasma source 30e includes an RF power source 16, an electromagnetic wave radiation mechanism 18b, a dielectric window 20d, a dielectric body 20e, and a resonator array structure 400. The remote plasma source 30e may include a gas supply 38, as in the second embodiment.

The electromagnetic wave radiation mechanism 18b corresponds to the antenna 18 of the second embodiment and supplies electromagnetic waves, such as microwaves, to the resonator array structure 400. The electromagnetic wave radiation mechanism 18b includes a cylindrical outer conductor and an inner conductor arranged coaxially with the outer conductor within the outer conductor. The electromagnetic wave radiation mechanism 18b includes a coaxial tube having an electromagnetic wave transmission line between the outer conductor and the inner conductor, and an antenna part that radiates electromagnetic waves to the resonator array structure 400. A dielectric window 20d that forms part of the wall of the pipe 36 is provided on the underside of the antenna part, and the lower surface thereof is in contact with the surface of the resonator array structure 400 on which the cells C are not formed. The resonator array structure 400 is arranged within the pipe 36. The electromagnetic waves transmitted through the dielectric window 20d generate a rotating magnetic field H1 centered on the inner conductor of the electromagnetic wave radiation mechanism 18b, thereby generating plasma in the cell space within each cell C of the resonator array structure 400. The rotating magnetic field H1 is caused by the power introduction structure of the electromagnetic wave radiation mechanism 18b, i.e., by the electromagnetic waves propagating through a coaxial tube in a TEM mode. That is, on the lower surface of the dielectric window 20d where the resonator array structure 400 is arranged, the electromagnetic waves supplied from the antenna part is in a TM01 mode. Therefore, the direction of the magnetic field may be considered to be the rotating magnetic field H1.

The dielectric window 20d is provided on the sidewall of the pipe 36, and a portion of the dielectric window 20d protrudes into the internal space 36h so as to contact the resonator array structure 400. The dielectric body 20e is arranged within the pipe 36 and is in cooperation with the dielectric window 20d to sandwich the resonator array structure 400, which is arranged in the central portion of the pipe 36 in the cross-sectional direction. In other words, the cross section of the pipe 36 at the position where the dielectric window 20d and other components are arranged is blocked by the dielectric window 20d, the resonator array structure 400, and the dielectric body 20e in the named order from the dielectric window 20d side. The processing gas flowing within the pipe 36 can flow toward the nozzle 41 by passing through the through-holes 415 of the resonators 401 that constitute each cell C of the resonator array structure 400.

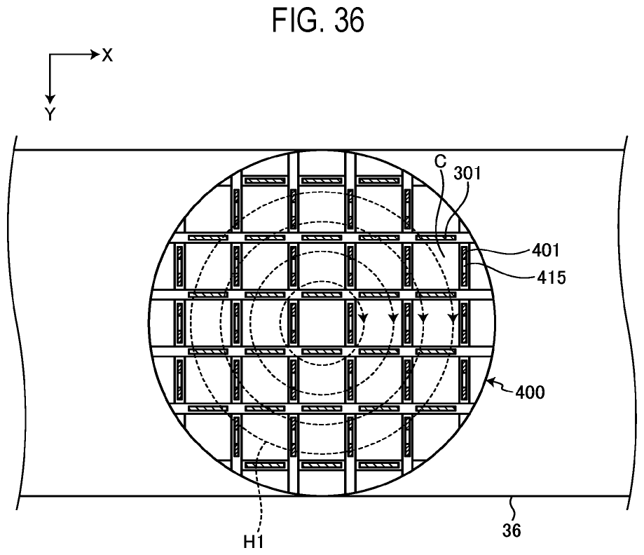

FIG. 36 is a cross-sectional view showing an example of the K-K cross section in FIG. 35. As shown in FIG. 36, the resonator array structure 400 is a cell-shaped resonator array structure similar to the resonator array structure 300 of the second embodiment. The resonator array structure 400 has through-holes 415 provided in the resonators 401 arranged in the Y-axis direction in FIG. 36, which is substantially perpendicular to the flow direction of the processing gas in the pipe 36, instead of the through-holes 325 in the base plate 320 of the resonator array structure 300. That is, the resonator array structure 400 includes cells C formed by the resonators 301 arranged in the X-axis direction in FIG. 36 and the resonators 401 arranged in the Y-axis direction. In the resonators 301 and 401 of each cell C, the rotating magnetic field H1 passes through the respective ring members (ring members 311 and 411), causing the resonators 301 and 401 to resonate, thereby exciting plasma in the cell space within each cell C.

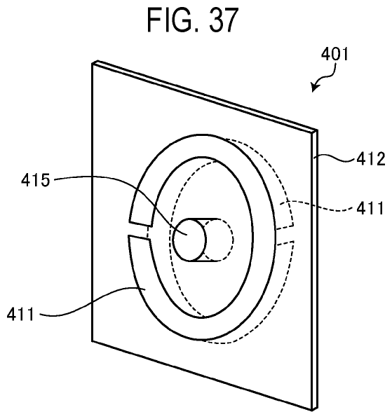

FIG. 37 is a view showing an example of the configuration of the resonator according to Modification 7. The resonator 401 shown in FIG. 37 has a structure in which a dielectric plate 412 is arranged between two C-shaped conductor ring members 411 that are arranged adjacent to each other in opposite directions. That is, in the resonator 401, the dielectric plate 412 is sandwiched between the two C-shaped ring members 411 that are arranged in opposite directions. Capacitor-equivalent elements are formed on the opposing surfaces of the two C-shaped ring members 411 and on both ends of each ring member 411, and coil-equivalent elements are formed along each ring member 411. This allows the resonator 401 to form a series resonant circuit. The resonator 401 also has a through-hole 415 at its center. By providing the through-hole 415, in the cells C whose two opposing surfaces are formed by the resonators 401, gas and plasma can flow between the cells C adjacent to each other in the X-axis direction in FIG. 36. The resonator 401 can also be expressed as being formed by a set of two C-shaped ring members 411. In the following description, the dielectric plate 412 may be referred to as a dielectric body 412.

As described above, in Modification 7, even if the electromagnetic wave radiation mechanism 18b that supplies the rotating magnetic field H1 and the cell-shaped resonator array structure 400 are used, high-density radicals can be generated while suppressing the influence of heat, electromagnetic waves, and ions, as in the second embodiment.

### Modification 8

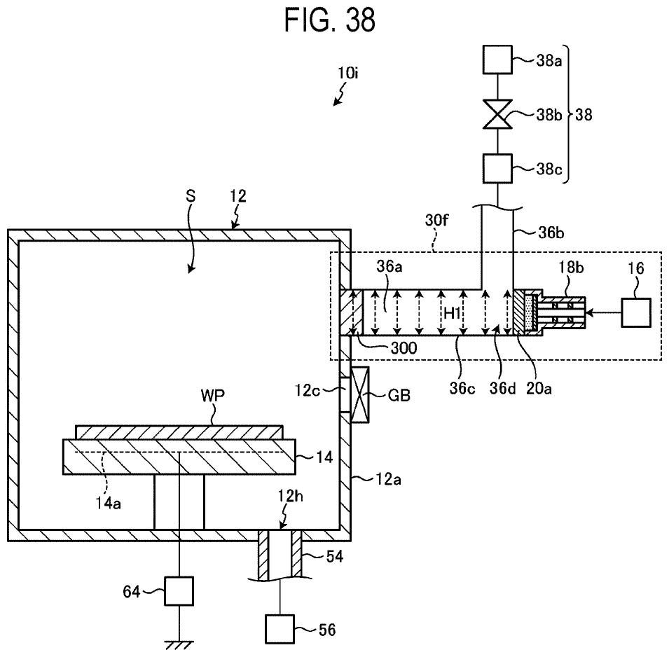

FIG. 38 is a schematic cross-sectional view showing an example of the configuration of a plasma processing apparatus according to Modification 8. The apparatus body 10i of Modification 8 shown in FIG. 38 includes a 180 degree-inverted resonator array structure 300 arranged at the position of the nozzle 41 compared to the apparatus body 10g of the second embodiment. Electromagnetic waves are supplied from the same position as in Modification 5 of the first embodiment. Just like Modification 5 of the first embodiment, the apparatus body 10i also includes pipes 36b and 36c instead of the pipe 36. The resonator array structure 300 is provided on the processing container 12 side of the pipe 36c so as to block the cross section of the pipe 36c. Furthermore, a dielectric window 20a is provided at a connection portion 36d between the pipes 36b and 36c, and an electromagnetic wave emission mechanism 18b is arranged so as to be able to supply a rotating magnetic field H1 to the resonator array structure 300 via the dielectric window 20a. In other words, the apparatus body 10i includes a remote plasma source 30f instead of the remote plasma source 30d. The remote plasma source 30f may include a gas supply 38, as in the second embodiment.

The pipes 36b and 36c are connected to each other at the connection portion 36d, for example, at a right angle. In the connection portion 36d, a dielectric window 20a is provided on a wall surface facing the surface on which the cells C of the resonator array structure 300 are formed, as viewed from the electromagnetic wave radiation mechanism 18b side. The pipes 36b and 36c may be connected at any angle as long as the rotating magnetic field H1 from the electromagnetic wave radiation mechanism 18b can be supplied to the resonator array structure 300 via the dielectric window 20a.

As in Modification 5, the resonator array structure 300 is arranged so that the surface on which each cell C is formed faces the upstream side of the pipe 36, i.e., the internal space 36a side. In this case, the through-hole 325 has a diameter of, for example, 10 mm or less, which allows ions to be recombined and allows radicals and inactivated processing gases to pass from the internal space 36a to the processing space S. More preferably, the through-hole 325 has a diameter of, for example, 2 mm or less. In other words, the through-hole 325 has a diameter that does not allow ions to pass from the internal space 36a to the processing space S.

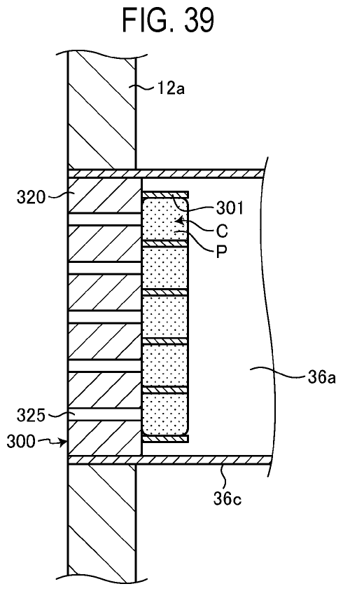

FIG. 39 is a view showing an example of a cross section near the resonator array structure according to Modification 8. As shown in FIG. 39, the resonator array structure 300 is provided at the end of the pipe 36c, and the base plate 320 has the same thickness as the side wall 12 a. In FIG. 39, the thicknesses are depicted as being slightly different. In the resonator array structure 300, plasma P is generated in the cell space of each cell C on the internal space 36a side. The plasma P generated in each cell C passes through each through-hole 325 of each cell C provided in the base plate 320 and is supplied to the side of the resonator array structure 300 on which no cells C are formed, i.e., the processing space S. At this time, ions in the plasma P are recombined through the through-hole 325 and supplied as radicals to the processing space S.

By combining the second embodiment with Modification 5 as described above, the nozzle 41 can be omitted. Furthermore, in Modification 8, the distance between the plasma generation region of the resonator array structure 300 and the processing space S is shorter than that in the second embodiment, so that radicals can be supplied at a higher density. Furthermore, as in Modification 5, the degree of freedom in arranging the remote plasma source 30f can be improved.

### Third Embodiment

In the second embodiment described above, the cell-shaped resonator array structures 300 and 400 are used. Alternatively, a resonator array structure in which the resonators extend radially from the center of the resonator array structure may also be used. The embodiment in this case will be described as a third embodiment. The plasma processing apparatus 3 according to the third embodiment is the same as those of the first and second embodiments described above except for the configuration of the remote plasma source. Therefore. the descriptions of the overlapping configurations and operations will be omitted.

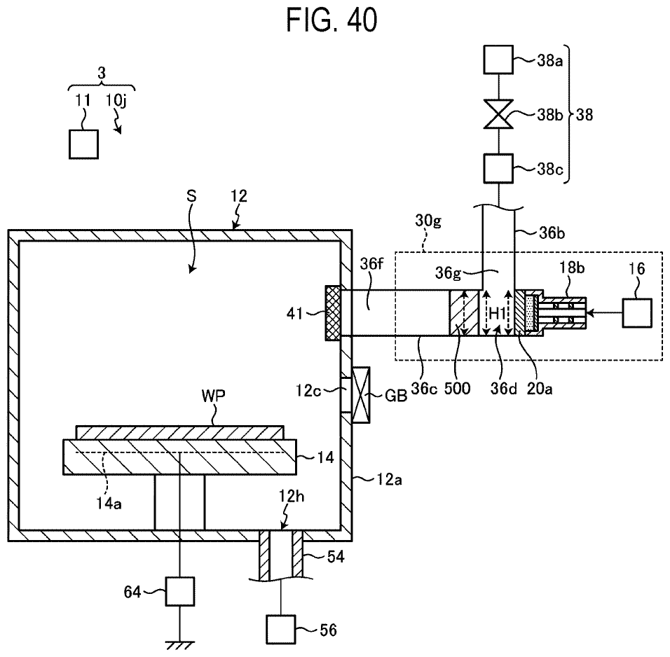

FIG. 40 is a schematic cross-sectional view showing an example of the configuration of the plasma processing apparatus according to the third embodiment. As shown in FIG. 40, the apparatus body 10j of the third embodiment includes a remote plasma source 30g instead of the remote plasma source 30d of the second embodiment. The remote plasma source 30g includes an RF power source 16, an electromagnetic wave radiation mechanism 18b, a dielectric window 20a, and a resonator array structure 500 arranged within the pipe 36c. That is, the third embodiment is different from Modification 8 in that a nozzle 41 is provided and a resonator array structure 500 is arranged within the pipe 36c. The remote plasma source 30g may include a gas supply 38, as in the second embodiment.

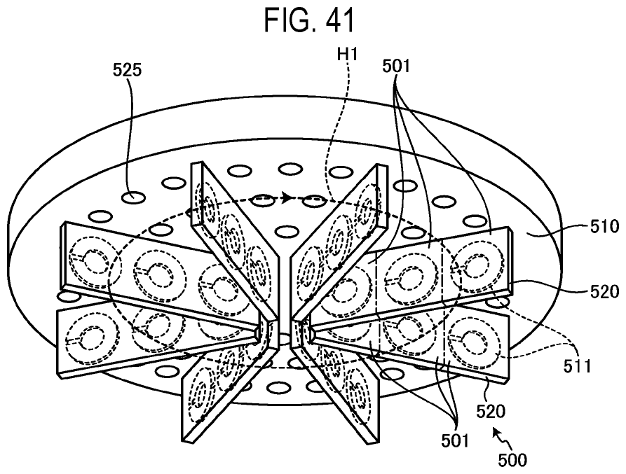

FIG. 41 is a perspective view showing an example of the resonator array structure according to the third embodiment. The resonator array structure 500 shown in FIG. 41 is formed to include a plurality of resonators 501 that can resonate with the magnetic field component of microwaves and that are each smaller in size than the wavelength of the microwaves. That is, the plurality of resonators 501 may also be expressed as being arranged in a direction of a plane perpendicular to the first surface of the resonator array structure 500 on which a base has a larger area, i.e., in a coplanar direction that can rotate about the center of the resonator array structure 500. The plurality of resonators 501 form a plurality of strip-shaped resonators 520, each of which is formed by connecting a plurality of resonators 501 horizontally. In the example shown in FIG. 41, each strip-shaped resonator 520 includes three resonators 501 connected together. The plurality of strip-shaped resonators 520 are arranged so that the short sides of the strips are perpendicular to the plane of the base plate 510 and extend radially from the central axis of the electromagnetic wave radiation mechanism 18b. The rotating magnetic field H1 of the electromagnetic waves supplied from the electromagnetic wave radiation mechanism 18b is directed to pass through the ring members 511 of the resonators 501 of the plurality of strip-shaped resonator 520.

The base plate 510 is provided with a plurality of through-holes 525. Just like the through-holes 325 of the resonator array structure 300, the through-holes 525 connect the internal space 36f and the internal space 36g, allowing the processing gas to flow from the pipe 36b side to the pipe 36c side. Details of the resonators 501 are the same as those of the resonators 301B of the second embodiment, and therefore the descriptions thereof will not be omitted. Each of the resonators 501 has a size less than 1/10 of the wavelength of the electromagnetic waves. The resonator array structure 500 is arranged such that the side on which the strip-shaped resonator 520 is formed faces the downstream side of the pipe 36c, i.e., the processing space S. The resonator array structure 500 may have a structure in which the base plate 510 is omitted and the strip-shape resonator 520 is connected by welding, for example.

Next, the generation of high-density radicals in the remote plasma source 30g of the plasma processing apparatus 3 will be described. As shown in FIG. 40, in the resonator array structure 500, the rotating magnetic field H1 passes through each resonator 501 of the strip-shaped resonator 520, causing each resonator 501 to resonate, thereby exciting plasma P on the surface of each resonator 501. That is, the vicinity of each strip-shaped resonator 520 serves as a plasma generation region. Since the processing gas is supplied from the gas supply 38 to the processing space S, a flow moving toward the processing space S is generated in the internal space 36f of the pipe 36c. Therefore, the processing gas supplied from the gas supply 38 to the internal space 36f through the through-holes 525 excites plasma P near each strip-shaped resonator 520 and flows into the processing space S through the through-holes 41a of the nozzle 41. The through-holes 41a of the nozzle 41 function as ion traps. That is, high-density radicals are supplied to the processing space S from the through-holes 41a of the nozzle 41. The workpiece WP is processed by the high-density radicals supplied to the processing space S.

Even when the radial resonator array structure 500 is used in this way, high-density radicals can be generated while suppressing the influence of heat, electromagnetic waves, and ions, as in the first and second embodiments.

### Modification 9

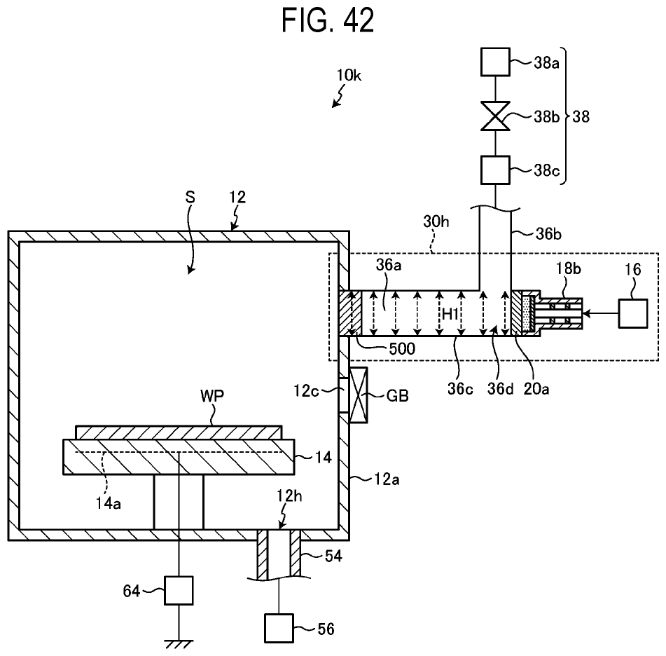

Next, Modification 9 of the third embodiment will be described using FIG. 42. In Modification 9 described below, the same components as those of the apparatus bodies 10, 10g, and 10j of the first to third embodiments are designated by like reference numerals, and the descriptions of the overlapping components and operations will be omitted. FIG. 42 is a schematic cross-sectional view showing an example of the configuration of a plasma processing apparatus according to Modification 9. The apparatus body 10k of Modification 9 shown in FIG. 42 includes a 180 degree-inverted resonator array structure 500 arranged at the position of the nozzle 41 compared to the apparatus body 10j of the third embodiment. The resonator array structure 500 is provided on the processing container 12 side of the pipe 36c so as to block the cross section of the pipe 36c. In other words, the apparatus body 10k includes a remote plasma source 30h instead of the remote plasma source 30g. The remote plasma source 30h may include a gas supply 38, as in the third embodiment.

As in Modification 8, the resonator array structure 500 is arranged such that the surface on which each strip-shaped resonator 520 is formed faces the upstream side of the pipe 36c, i.e., the internal space 36a. In this case, the through-holes 525 have a diameter of, for example, 10 mm or less, so that ions are recombined and radicals and inactivated processing gases pass from the internal space 36a to the processing space S. More preferably, the through-holes 525 have a diameter of, for example, 2 mm or less. In other words, the through-holes 525 have a diameter that does not allow ions to pass from the internal space 36a to the processing space S.

In this way, in Modification 9, the nozzle 41 can be omitted by combining the third embodiment with Modification 8. Furthermore, in Modification 9, the distance between the plasma generation region of the resonator array structure 500 and the processing space S is shorter than that in the third embodiment, so that radicals can be supplied at a higher density. Furthermore, as in Modification 8, the degree of freedom in arranging the remote plasma source 30h can be improved.

### Fourth Embodiment

Unlike the first to third embodiments, the plasma density may be measured to control the flow rate of the processing gas and the power of the source RF signal. The embodiment in this case will be described as a fourth embodiment. The plasma processing apparatus 4 according to the fourth embodiment is the same as those of the first to third embodiments except for the configuration of an insulating probe and the control based on a plasma density. Therefore, the descriptions of the overlapping configurations and operations will be omitted.

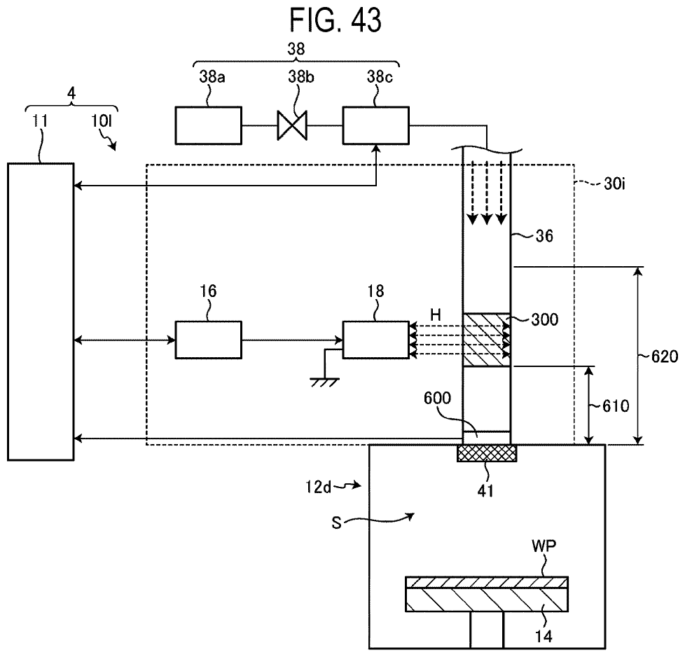

FIG. 43 is a block diagram showing an example of the configuration of the plasma processing apparatus according to the fourth embodiment. As shown in FIG. 43, the apparatus body 101 of the fourth embodiment differs from the apparatus body 10g of the second embodiment in that an insulating probe 600 is provided on the pipe 36 side of the nozzle 41. The insulating probe 600 is an example of a measurement part. The processing container 12d and the nozzle 41 are arranged in the same manner as in the apparatus body 10a of Modification 1. In the fourth embodiment, the remote plasma source 30i includes at least an RF power source 16, an antenna 18, a resonator array structure 300, and an insulating probe 600. The remote plasma source 30i may include a gas supply 38, as in the second embodiment.

The insulating probe 600 is arranged, for example, on the pipe 36 side of the nozzle 41, and is configured to measure the electron density of the plasma generated in the resonator array structure 300. The distance 610 between the resonator array structure 300 and the insulating probe 600 in the pipe 36 is the diffusion length of the plasma diffusion region in which the plasma diffuses. The insulating probe 600 outputs the measured plasma density to the controller 11.

Now, a region 620 including the resonator array structure 300 and the insulating probe 600 will be described with reference to FIG. 44. FIG. 44 is a view showing an example of the plasma diffusion region according to the fourth embodiment. As shown in FIG. 44, in the region 620, the processing gas flows from the internal space 36g of the pipe 36 toward the internal space 36f. The flow rate of the processing gas also varies depending on the diameter 36i of the pipe 36. The diameter of the resonator array structure 300 is approximately equal to the diameter (inner diameter) 36i of the pipe 36. When the processing gas passes through the resonator array structure 300 to which the magnetic field His applied, plasma P is generated and diffused within the internal space 36f. FIG. 44 shows the plasma P in a schematic representation. Ions contained in the plasma P are recombined as they pass through the through-holes 41a of the nozzle 41. Radicals contained in the plasma P are supplied to the processing space S together with the inactivated processing gas.

The insulating probe 600 is arranged, for example, on the internal space 36f side of the nozzle 41, on the processing space S side, or inside the sidewall of the pipe 36 near the nozzle 41 to measure the plasma density near the nozzle 41. As the plasma density, for example, an electron density is measured.

When the controller 11 receives the electron density as a measurement result from the insulating probe 600, it controls the remote plasma source 30i to adjust the plasma supply amount based on the input electron density. That is, the controller 11 controls the power of the source RF signal of the RF power source 16 based on the electron density. The controller 11 also controls the flow rate of the processing gas (raw material gas) by controlling the flow rate controller 38c of the gas supply 38 based on the electron density. This allows the plasma processing apparatus 4 to control the amount of high-density radicals generated.

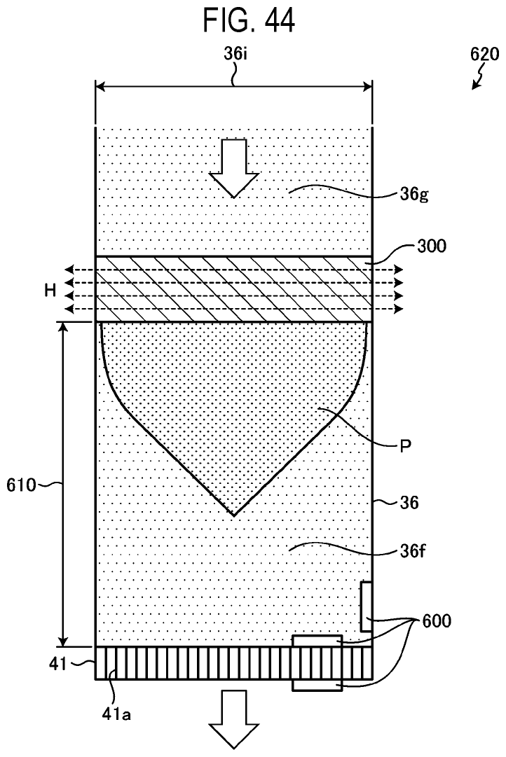

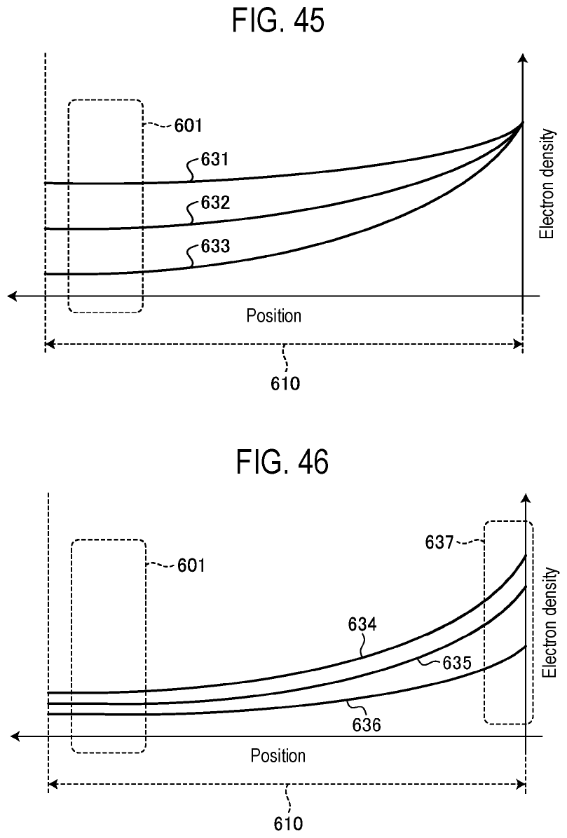

Next, the change in electron density over distance 610, which is the diffusion length of the plasma diffusion region, will be described using FIGS. 45 and 46. FIGS. 45 and 46 are graphs showing an example of the distribution of electron density in the plasma diffusion region. In FIGS. 45 and 46, the region 620 shown in FIG. 44 is rotated 90 degrees to the right, so that the resonator array structure 300 is located on the right side of the graph and the nozzle 41 is located on the left side of the graph.

FIG. 45 shows an example of the distribution of electron density according to the flow rate of the processing gas at the distance 610, wherein the region 601 represents the measurement position of the insulating probe 600. Graphs 631 to 633 show the distribution of electron density when the flow rate of the processing gas is high (graph 631), medium (graph 632), and low (graph 633), respectively. The flow rates in graphs 631 to 633 are relative. It can be seen from graphs 631 to 633 that the electron density at the insulating probe 600 near the nozzle 41 increases as the flow rate of the processing gas increases (becomes greater). Due to the Boltzmann relationship, the electron density decreases at locations where the electron temperature is high.

FIG. 46 shows an example of the distribution of electron density at the distance 610 depending on the power of the source RF signal (hereinafter sometimes simply referred to as power) of the RF power source 16, wherein the region 601 represents the measurement position of the insulating probe 600. Graphs 634 to 636 show the distribution of electron density when graph 634 is high power, graph 635 is medium power, and graph 636 is low power, respectively. The powers in graphs 634 to 636 are relative. Graphs 634 to 636 show that the electron density in the region 637 on the resonator array structure 300 side increases as the power becomes higher. FIGS. 45 and 46 show that the electron density in the insulating probe 600 near the nozzle 41 can be controlled by the flow rate of the processing gas and the power.

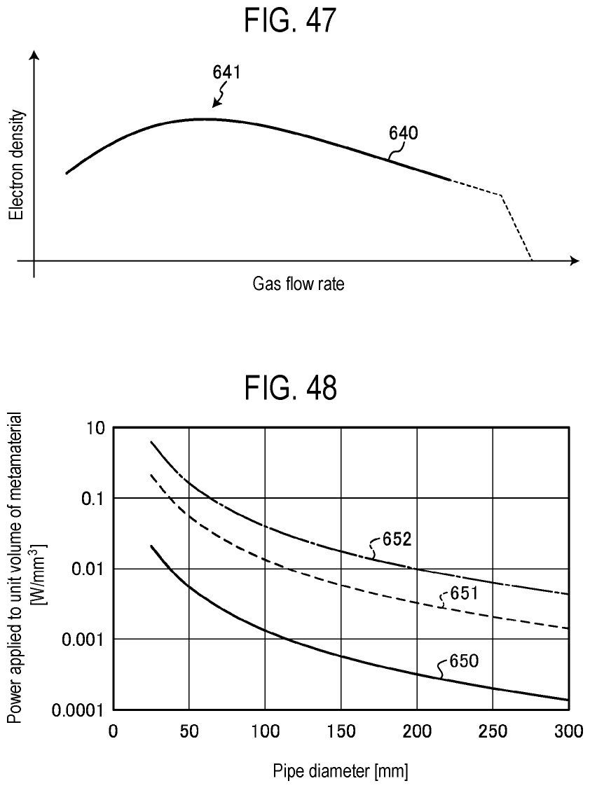

Next, the relationship between the flow rate of the processing gas, the electron density, the diameter 36i of the pipe 36, the power, the residence time, and the travel time will be described using FIGS. 47 to 51. FIG. 47 is a graph showing an example of the relationship between the gas flow rate and the electron density. Graph 640 in FIG. 47 shows the relationship between the gas flow rate (i.e., the flow rate of the processing gas) and the electron density. When the gas flow rate is low, diffusion is the dominant factor in the plasma diffusion region (internal space 36f). As shown in graph 640, when the gas flow rate increases to the vicinity of the region 641, plasma generation in the resonator array structure 300 is promoted not only by the diffusion but also by the gas flow, resulting in an increase in electron density. However, if the gas flow rate increases further, plasma generation in the resonator array structure 300 cannot keep up, and the electron density decreases. Therefore, it is preferable to control the gas flow rate to the vicinity of the region 641.

FIG. 48 is a graph showing an example of the relationship between the electromagnetic wave power and the pipe diameter. In the graph of FIG. 48, the vertical axis represents the power [W/mm³] applied to a unit volume of the resonator array structure 300 (metamaterial), and the horizontal axis represents the diameter 36i [mm] of the pipe 36 (hereinafter referred to as pipe diameter). Graph 650 represents a case where the power of the source RF signal of the RF power source 16 is 100 W. Graph 651 represents a case where the power is 1000 W. Graph 652 represents a case where the power is 3000 W.

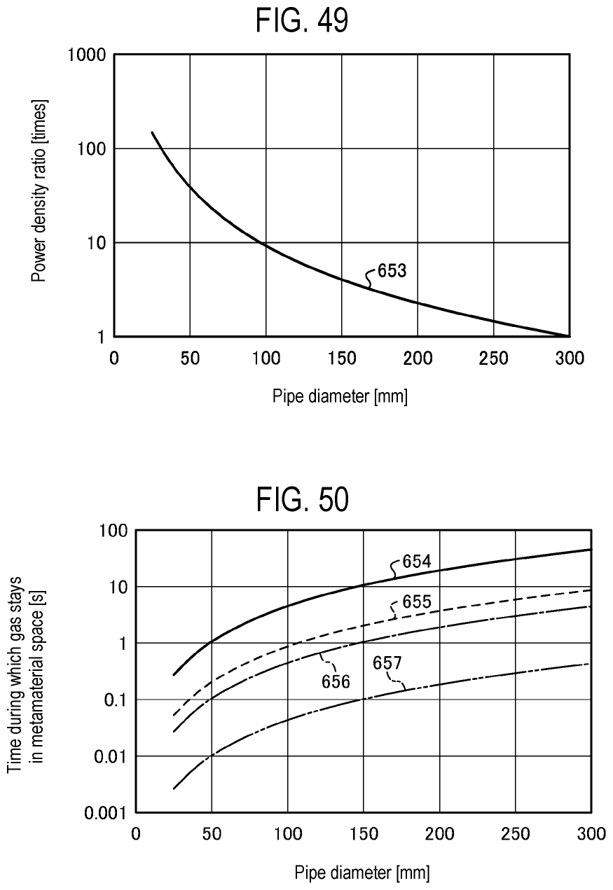

FIG. 49 is a graph showing an example of the relationship between the power density ratio of electromagnetic waves and the pipe diameter. In graph 653 of FIG. 49, the vertical axis represents the power density ratio [times] and the horizontal axis represents the pipe diameter [mm]. The vertical axis of graph 653 represents the ratio, with the pipe diameter of 300 [mm] being 1 times. When power is supplied to the resonator array structure 300, plasma is generated. As shown in graphs 650 to 653, the smaller the pipe diameter and the greater the input power, the greater the power applied per unit volume. In other words, in the resonator array structure 300, the greater the power supplied to the resonator array structure 300, the more ionization of the processing gas in the resonator array structure 300 progresses, resulting in a higher plasma density. Furthermore, in the resonator array structure 300, the power density increases as the pipe diameter decreases. In other words, in each embodiment, high-density plasma can be generated.

FIG. 50 is a graph showing an example of the relationship between the time during which a gas stays in the space of the resonator array structure and the pipe diameter. In the graph of FIG. 50, the vertical axis represents the time [s] during which the processing gas stays in the space of the resonator array structure 300 (metamaterial), and the horizontal axis represents the pipe diameter [mm]. Here, the vertical axis corresponds to the time during which power is applied to the processing gas. Graph 654 shows a case where the flow rate of the processing gas is 1000 sccm (1.67×10⁻⁵ m³/s). Graph 655 shows a case where the flow rate of the processing gas is 5000 sccm. Graph 656 shows a case where the flow rate of the processing gas is 10,000 sccm. Graph 657 shows a case where the flow rate of the processing gas is 100,000 sccm. When the processing gas flows through the pipe 36, the processing gas in the space of the resonator array structure 300 is replaced. Therefore, as shown in graphs 654 to 657, the smaller the pipe diameter and the higher the flow rate of the processing gas, the shorter the time during which the processing gas stays in the space of the resonator array structure 300. In other words, the smaller the pipe diameter and the higher the flow rate of the processing gas, the faster the gas replacement in the space of the resonator array structure 300. In other words, in the resonator array structure 300, gas replacement occurs immediately after plasma is generated, and high-density plasma is generated one after another.

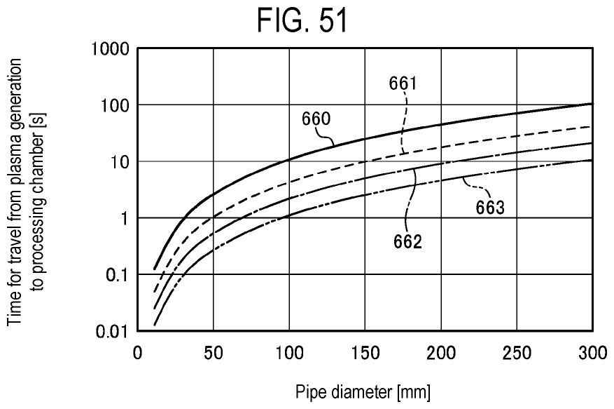

FIG. 51 is a graph showing an example of the relationship between the travel time from plasma generation to the processing chamber and the pipe diameter. In the graph of FIG. 51, the vertical axis represents the time [s] during which the plasma generated in the resonator array structure 300 travels to the processing space S (processing chamber), and the horizontal axis represents the pipe diameter [mm]. Here, the vertical axis corresponds to the time it takes for the plasma to travel the distance 610. Graph 660 shows a case where the flow rate of the processing gas is 2000 sccm. Graph 661 shows a case where the flow rate of the processing gas is 5000 sccm. Graph 662 shows a case where the flow rate of the processing gas is 10000 sccm. Graph 663 shows a case where the flow rate of the processing gas is 20000 sccm. As shown in graphs 660 to 663, the smaller the pipe diameter, the shorter the time it takes for the plasma generated in the resonator array structure 300 to travel from plasma generation to the processing space S.

As described above, the fourth embodiment enables optimal control of the flow rate of the processing gas relative to the power. Furthermore, as in the second to fourth embodiments and Modifications 5, 6, 8, and 9, the resonator array structure has a diameter substantially equal to that of the pipes 36 and 36c (e.g., φ100 mm or less), which makes it possible to reduce the size of the remote plasma source. Furthermore, since the size of the resonator array structure can be reduced, the power density increases at low power, which makes it possible to generate high-density plasma exceeding the cutoff density. Therefore, high-density radicals can be generated. Furthermore, since the volume of the internal spaces 36a and 36f, which are the plasma generation regions in the pipes 36 and 36c, is small, it is possible to shorten the time it takes for the plasma to reach the processing space S. Accordingly, the number of radicals recombined can be reduced, which makes it possible to supply high-density radicals to the processing space S.

Furthermore, the above-described embodiments and modifications may be combined as appropriate within the scope of the present disclosure without causing any contradiction in content. For example, the orifice 42 of Modification 4 may be used in place of the nozzle 41 of the second embodiment.

According to each of the above-described embodiments, each of the plasma processing apparatuses 1 to 4 includes a processing chamber (processing container 12, 12d, or 12e), a substrate holder (stage 14), and a plasma source (remote plasma source 30, or 30a to 30h). The processing chamber is configured to provide a processing space S for a substrate (workpiece WP). The substrate holder is configured to hold a substrate within the processing chamber. The plasma source is configured to supply plasma into the processing chamber and includes a gas supply 38, a pipe (pipe 36, 36c, or 36e), an electromagnetic wave generator (RF power source 16), an electromagnetic wave supply (antenna 18 or 18a, or electromagnetic wave radiation mechanism 18b), and a resonator array structure (resonator array structure 100, 200, 300, 400, or 500). The gas supply 38 is configured to supply a raw material gas. The pipe is configured to connect the gas supply 38 to the processing chamber. The electromagnetic wave generator is configured to generate electromagnetic waves for plasma excitation to be supplied into the pipe. The electromagnetic wave supply is configured to supply the electromagnetic waves into the pipe through a dielectric window (dielectric window 20, or 20a to 20d) provided in the pipe. The resonator array structure is configured to include a plurality of resonators (resonators 101, 201, 301, 401, or 501) that can resonate with the magnetic field component of the electromagnetic waves, have a size smaller than the wavelength of the electromagnetic waves, and are arranged in the coplanar direction. As a result, high-density radicals can be generated while suppressing the influence of heat, electromagnetic waves, and ions.

Furthermore, according to each of the above-described embodiments, the plurality of resonators have a structure in which C-shaped ring members (ring members 111, 211, 311, 411, or 511) made of a conductor are stacked on a dielectric body (e.g., dielectric body 112, 212, 312, or 412). As a result, it is possible to excite plasma.

Furthermore, according to the first embodiment, each of the plurality of resonators 101 or 201 includes a set of two or more C-shaped ring members 111 or 211, and are formed in a direction of a plane parallel to a first surface (first surface 106 or 206) of the resonator array structure 100 or 200 on which a base (dielectric body 112 or 212) has a larger area. As a result, the plurality of resonators 101 or 201 can resonate with a magnetic field H supplied from the electromagnetic wave supply in a direction in which the magnetic field H passes through the resonators 101 or 201.

Furthermore, according to the second and third embodiments, each of the plurality of resonators 301, 401 or 501 is formed in a card shape for a set of two or more C-shaped ring members 311, 411, or 511. The plurality of card-shaped resonators 301, 401 or 501 are formed in the direction of a plane parallel to a first surface of the resonator array structure 300, 400, or 500 on which a base (e.g., base plate 320 or 510) has a larger area. As a result, the plurality of resonators 301, 401 or 501 can resonate with the magnetic field H or rotating magnetic field H1 supplied from the electromagnetic wave supply and passing through the resonators 301, 401 or 501.

Furthermore, according to the second and third embodiments, each of the plurality of resonators 301, 401 and 501 includes a set of two or more C-shaped ring members 311, 411, or 511, and are formed in a strip shape (e.g., a strip-shaped resonator 520) by connecting the plurality of sets. The plurality of strip-shaped resonators are formed in a direction of a plane parallel to a first surface of the resonator array structure 300, 400, or 500 on which a base (e.g., base plate 320 or 510) has a larger area. As a result, the plurality of resonators 301, 401 or 501 can resonate with the magnetic field H or rotating magnetic field H1 supplied from the electromagnetic wave supply and passing through the resonators 301, 401 or 501.

Furthermore, according to the third embodiment, the plurality of resonators 501 are arranged on the side of the first surface of the resonator array structure 500 such that the plate-shaped dielectric body of each of the resonators 501 extends radially from the central axis of the electromagnetic wave supply as a starting point. As a result, the plurality of resonators 501 can resonate with the rotating magnetic field H1 supplied from the electromagnetic wave supply and passing through the resonators 501.

Furthermore, according to the first embodiment and Modifications 1 to 4 and 7, the resonator array structure 100 or 400 is arranged such that the first surface thereof is parallel to the longitudinal direction of the pipe 36. As a result, the electromagnetic supply wave part can be arranged in a direction extending along the sidewall of the pipe 36.

Furthermore, according to the second and third embodiments and Modifications 5, 6 and 8, the resonator array structure 200, 300, or 500 is arranged so that the first surface thereof is parallel to the cross-sectional direction of the pipe 36 or 36c. As a result, plasma can be generated over the entire cross-section of the pipe 36 or 36c.

Furthermore, according to the first to third embodiments and Modifications 1 to 3 and 7, the pipe 36 or 36c is provided with a nozzle 41 at a connection portion with the processing chamber. As a result, high-density radicals can be supplied to the processing chamber while suppressing the influence of heat, electromagnetic waves, and ions.

Furthermore, according to Modification 7, the resonator array structure 400 is arranged at the center of the cross section of the pipe 36. Each of the plurality of resonators 401 has a through-hole 415 in the plate-shaped dielectric body of the resonator 401. As a result, the processing gas passing through the through-hole 415 can be plasma-excited.

According to the second and third embodiments and Modifications 5, 6 and 8, the resonator array structure 200, 300 or 500 includes through-holes 208, 325, and 525 opened on the first surface. As a result, the processing gas can be caused to flow from the gas supply 38 to the processing space S.

According to the fourth embodiment, the plasma source further includes a measurement part (insulating probe 600) arranged in the pipe 36 at a position closer to the processing chamber than the resonator array structure 300 and configured to measure a plasma density. The plasma processing apparatus 4 further includes a control part (controller 11) configured to control the plasma source to adjust a plasma supply amount based on the measurement results of the measurement part. As a result, the flow rate of the processing gas relative to the power can be optimally controlled.

Furthermore, according to the fourth embodiment, the controller is configured to control the output of the electromagnetic waves from the electromagnetic wave generator based on the measurement results. As a result, the plasma density can be controlled by the power of the source RF signal.

Furthermore, according to the fourth embodiment, the controller is configured to control, based on the measurement results, the flow rate of the raw material gas (processing gas) supplied from the gas supply 38. As a result, the plasma density can be controlled by the flow rate of the processing gas.

The embodiments disclosed herein should be considered to be exemplary and not limitative in all respects, and various omissions, substitutions, and modifications may be made to the above-described embodiments without departing from the spirit and scope of the appended claims.

Furthermore, in the above-described embodiments, the antenna 18, which is a solenoid coil, or the electromagnetic wave radiation mechanism 18b having a coaxial tube and an antenna part is used as the antenna for emitting electromagnetic waves. However, the present disclosure is not limited thereto. In other words, the present disclosure is not limited thereto as long as the antenna can generate a magnetic field in a direction in which the magnetic field passes through the ring member 111 of the plurality of resonators 101 of the resonator array structure 100. The antenna for emitting such electromagnetic waves is not limited to the antenna 18 or the electromagnetic wave radiation mechanism 18b, and any antenna or mechanism for emitting electromagnetic waves, such as a monopole antenna, a slot antenna, an inductively coupled coil, a capacitively coupled electrode, or a magnetron, may be used.

In the above-described embodiments, plasma is generated by the independent remote plasma source 30 or the like. However, the present disclosure is not limited thereto. For example, the remote plasma source 30 or the like may be combined with a capacitively coupled or inductively coupled plasma processing apparatus that generates plasma directly in the processing space S of the processing container 12.

According to the present disclosure, it is possible to generate high-density radicals while suppressing the influence of heat, electromagnetic waves and ions.

The present disclosure may also be configured as follows.

(1) A plasma processing apparatus, comprising:
a processing chamber configured to provide a processing space for a substrate;
a substrate holder configured to hold the substrate within the processing chamber; and
a plasma source configured to supply plasma into the processing chamber, wherein the plasma source includes: a gas supply configured to supply a raw material gas; a pipe configured to connect the gas supply to the processing chamber; an electromagnetic wave generator configured to generate electromagnetic waves for plasma excitation to be supplied into the pipe; an electromagnetic wave supply configured to supply the electromagnetic waves into the pipe through a dielectric window provided in the pipe; and a resonator array structure configured to include a plurality of resonators which are capable of resonating with a magnetic field component of the electromagnetic waves, each smaller in size than the wavelength of the electromagnetic waves, and arranged in a coplanar direction.
   (2) The plasma processing apparatus of (1), wherein the plurality of resonators each has a structure in which C-shaped ring members made of a conductor are stacked on a dielectric body.
   (3) The plasma processing apparatus of (2), wherein each of the plurality of resonators includes a set of two or more C-shaped ring members and is formed in a direction of a plane parallel to a first surface of the resonator array structure on which a base has a larger area.
   (4) The plasma processing apparatus of (2), wherein each of the plurality of resonators includes a set of two or more C-shaped ring members and is formed in a card shape, and the plurality of card-shaped resonators are formed in a direction of a plane perpendicular to a first surface of the resonator array structure on which a base has a larger area.
   (5) The plasma processing apparatus of (2), wherein each of the plurality of resonators includes a set of two or more C-shaped ring members and is formed in a strip shape by connecting a plurality of sets of two or more C-shaped ring members, and wherein the plurality of strip-shaped resonators are formed in a direction of a plane perpendicular to a first surface of the resonator array structure on which a base has a larger area.
   (6) The plasma processing apparatus of (4) or (5), wherein the plurality of resonators are arranged on the first surface side of the resonator array structure so that a plate-shaped dielectric body of each of the resonators extends radially from a central axis of the electromagnetic wave supply.
   (7) The plasma processing apparatus of any one of (3) to (5), wherein the resonator array structure is arranged so that the first surface is parallel to a longitudinal direction of the pipe.
   (8) The plasma processing apparatus of any one of (3) to (6), wherein the resonator array structure is arranged so that the first surface is parallel to a cross-sectional direction of the pipe.
   (9) The plasma processing apparatus of (7), wherein the pipe is provided with a nozzle at a connection portion with the processing chamber.
   (10) The plasma processing apparatus of (7), wherein the resonator array structure is arranged at a center of a cross-section of the pipe, and wherein each of the plurality of resonators has a through-hole formed in the plate-shaped dielectric body of each of the plurality of resonators.
   (11) The plasma processing apparatus of (8) or (9), wherein the resonator array structure has a through-hole opened on the first surface.
   (12) The plasma processing apparatus of any one of (1) to (11), wherein the plasma source further includes a measurement part arranged in the pipe closer to the processing chamber than the resonator array structure and configured to measure a plasma density, and wherein the plasma processing apparatus further comprises a controller configured to control the plasma source to adjust a plasma supply amount based on measurement results of the measurement part.
   (13) The plasma processing apparatus of (12), wherein the controller is configured to control the output of the electromagnetic waves from the electromagnetic wave generator based on the measurement results.
   (14) The plasma processing apparatus of (12) or (13), wherein the controller is configured to control the flow rate of the raw material gas supplied from the gas supply based on the measurement results.
   (15) A plasma source, comprising:
a gas supply configured to supply a raw material gas;
a pipe configured to connect the gas supply to a processing chamber configured to provide a processing space for a substrate;
an electromagnetic wave generator configured to generate electromagnetic waves for plasma excitation to be supplied into the pipe;
an electromagnetic wave supply configured to supply the electromagnetic waves into the pipe through a dielectric window provided in the pipe; and
a resonator array structure configured to include a plurality of resonators which are capable of resonating with a magnetic field component of the electromagnetic waves, each smaller in size than the wavelength of the electromagnetic waves, and arranged in a coplanar direction.
   (16) The plasma source of (15), further comprising:
a measurement part arranged in the pipe closer to the processing chamber than the resonator array structure and configured to measure a plasma density; and
a controller configured to control one or more of the electromagnetic wave supply and the gas supply to adjust a plasma supply amount based on measurement results of the measurement part.
   (17) The plasma source of (16), wherein the controller is configured to control one or more of the output of the electromagnetic waves from the electromagnetic wave generator and the flow rate of the raw material gas of the gas supply based on the measurement results.
   (18) A plasma control method for a plasma processing apparatus, wherein the plasma processing apparatus includes: a processing chamber configured to provide a processing space for a substrate; a substrate holder configured to hold the substrate within the processing chamber; and a plasma source configured to supply plasma into the processing chamber,
wherein the plasma source includes: a gas supply configured to supply a raw material gas; a pipe configured to connect the gas supply to the processing chamber; an electromagnetic wave generator configured to generate electromagnetic waves for plasma excitation to be supplied into the pipe; an electromagnetic wave supply configured to supply the electromagnetic waves into the pipe through a dielectric window provided in the pipe; a resonator array structure configured to include a plurality of resonators which are capable of resonating with a magnetic field component of the electromagnetic waves, each smaller in size than the wavelength of the electromagnetic waves, and arranged in a coplanar direction; and a measurement part arranged in the pipe closer to the processing chamber than the resonator array structure and configured to measure a plasma density, and
wherein the plasma control method comprises controlling, by the plasma processing apparatus, the plasma source to adjust a plasma supply amount based on measurement results of the measurement part.
   (19) The plasma control method of (18), wherein the act of controlling of the plasma source includes controlling the output of the electromagnetic waves from the electromagnetic wave generator based on the measurement results.
   (20) The plasma control method of (18) or (19), wherein the act of controlling the plasma source includes controlling the flow rate of the raw material gas from the gas supply based on the measurement results.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing apparatus, comprising:
a processing chamber configured to provide a processing space for a substrate;
a substrate holder configured to hold the substrate within the processing chamber; and
a plasma source configured to supply plasma into the processing chamber,
wherein the plasma source includes:
a gas supply configured to supply a raw material gas; a pipe configured to connect the gas supply to the processing chamber; an electromagnetic wave generator configured to generate electromagnetic waves for plasma excitation to be supplied into the pipe; an electromagnetic wave supply configured to supply the electromagnetic waves into the pipe through a dielectric window provided in the pipe; and a resonator array structure configured to include a plurality of resonators which are capable of resonating with a magnetic field component of the electromagnetic waves, each smaller in size than a wavelength of the electromagnetic waves, and arranged in a coplanar direction.

2. The plasma processing apparatus of claim 1, wherein the plurality of resonators each has a structure in which C-shaped ring members made of a conductor are stacked on a dielectric body.

3. The plasma processing apparatus of claim 2, wherein each of the plurality of resonators includes a set of two or more C-shaped ring members and is formed in a direction of a plane parallel to a first surface of the resonator array structure on which a base has a larger area.

4. The plasma processing apparatus of claim 2, wherein each of the plurality of resonators includes a set of two or more C-shaped ring members and is formed in a card shape, and the plurality of card-shaped resonators are formed in a direction of a plane perpendicular to a first surface of the resonator array structure on which a base has a larger area.

5. The plasma processing apparatus of claim 2, wherein each of the plurality of resonators includes a set of two or more C-shaped ring members and is formed in a strip shape by connecting a plurality of sets of two or more C-shaped ring members, and
wherein the plurality of strip-shaped resonators are formed in a direction of a plane perpendicular to a first surface of the resonator array structure on which a base has a larger area.

6. The plasma processing apparatus of claim 4, wherein the plurality of resonators are arranged on the first surface side of the resonator array structure so that a plate-shaped dielectric body of each of the resonators extends radially from a central axis of the electromagnetic wave supply.

7. The plasma processing apparatus of claim 3, wherein the resonator array structure is arranged so that the first surface is parallel to a longitudinal direction of the pipe.

8. The plasma processing apparatus of claim 3, wherein the resonator array structure is arranged so that the first surface is parallel to a cross-sectional direction of the pipe.

9. The plasma processing apparatus of claim 7, wherein the pipe is provided with a nozzle at a connection portion with the processing chamber.

10. The plasma processing apparatus of claim 7, wherein the resonator array structure is arranged at a center of a cross-section of the pipe, and
wherein each of the plurality of resonators has a through-hole formed in the plate-shaped dielectric body of each of the plurality of resonators.

11. The plasma processing apparatus of claim 8, wherein the resonator array structure has a through-hole opened on the first surface.

12. The plasma processing apparatus of claim 1, wherein the plasma source further includes a measurement part arranged in the pipe closer to the processing chamber than the resonator array structure and configured to measure a plasma density, and
wherein the plasma processing apparatus further comprises a controller configured to control the plasma source to adjust a plasma supply amount based on measurement results of the measurement part.

13. The plasma processing apparatus of claim 12, wherein the controller is configured to control the output of the electromagnetic waves from the electromagnetic wave generator based on the measurement results.

14. The plasma processing apparatus of claim 12, wherein the controller is configured to control the flow rate of the raw material gas supplied from the gas supply based on the measurement results.

15. A plasma source, comprising:
a gas supply configured to supply a raw material gas;
a pipe configured to connect the gas supply to a processing chamber configured to provide a processing space for a substrate;
an electromagnetic wave generator configured to generate electromagnetic waves for plasma excitation to be supplied into the pipe;
an electromagnetic wave supply configured to supply the electromagnetic waves into the pipe through a dielectric window provided in the pipe; and
a resonator array structure configured to include a plurality of resonators which are capable of resonating with a magnetic field component of the electromagnetic waves, each smaller in size than a wavelength of the electromagnetic waves, and arranged in a coplanar direction.

16. The plasma source of claim 15, further comprising:
a measurement part arranged in the pipe closer to the processing chamber than the resonator array structure and configured to measure a plasma density; and
a controller configured to control one or more of the electromagnetic wave supply and the gas supply to adjust a plasma supply amount based on measurement results of the measurement part.

17. The plasma source of claim 16, wherein the controller is configured to control one or more of the output of the electromagnetic waves from the electromagnetic wave generator and the flow rate of the raw material gas of the gas supply based on the measurement results.

18. A plasma control method for a plasma processing apparatus, wherein the plasma processing apparatus includes: a processing chamber configured to provide a processing space for a substrate; a substrate holder configured to hold the substrate within the processing chamber; and a plasma source configured to supply plasma into the processing chamber,
wherein the plasma source includes: a gas supply configured to supply a raw material gas; a pipe configured to connect the gas supply to the processing chamber; an electromagnetic wave generator configured to generate electromagnetic waves for plasma excitation to be supplied into the pipe; an electromagnetic wave supply configured to supply the electromagnetic waves into the pipe through a dielectric window provided in the pipe; a resonator array structure configured to include a plurality of resonators which are capable of resonating with a magnetic field component of the electromagnetic waves, each smaller in size than a wavelength of the electromagnetic waves, and arranged in a coplanar direction; and a measurement part arranged in the pipe closer to the processing chamber than the resonator array structure and configured to measure a plasma density, and
wherein the plasma control method comprises controlling, by the plasma processing apparatus, the plasma source to adjust a plasma supply amount based on measurement results of the measurement part.

19. The plasma control method of claim 18, wherein the controlling of the plasma source includes controlling the output of the electromagnetic waves from the electromagnetic wave generator based on the measurement results.

20. The plasma control method of claim 18, wherein the controlling the plasma source includes controlling the flow rate of the raw material gas from the gas supply based on the measurement results.
